(19) United States
(12) Patent Application Publication
(10) Pub. No.: US 2024/0424801 A1
(43) Pub. Date: Dec. 26, 2024

(54) CHIP ASSEMBLY AND IMAGING MATERIAL BOX

(71) Applicant: E-Z INK TECHNOLOGY CO., LTD, Zhuhai (CN)

(72) Inventors: Wenyi FAN, Zhuhai (CN); Dongming LIN, Zhuhai (CN)

(73) Assignee: E-Z INK TECHNOLOGY CO., LTD, Zhuhai (CN)

(21) Appl. No.: 18/829,331

(22) Filed: Sep. 10, 2024

Related U.S. Application Data
(63) Continuation-in-part of application No. PCT/CN2023/114326, filed on Aug. 22, 2023.

(30) Foreign Application Priority Data
Aug. 22, 2022 (CN) 202222217229.3
Aug. 23, 2022 (CN) 202222228069.2
Aug. 29, 2022 (CN) 202222295294.8
Sep. 13, 2023 (CN) 202322496455.4
Mar. 20, 2024 (CN) 202420550005.0

(51) Int. Cl. B41J 2/175; H05K 1/18

(52) U.S. Cl. CPC B41J 2/1753; B41J 2/17523; B41J 2/17546; B41J 2/17553; H05K 1/181

(57) ABSTRACT

The provided are a chip assembly and an imaging material box. The chip assembly is configured to be installed in the imaging material box. The imaging material box is detachably installed on an imaging device provided with a stylus. The chip assembly includes a chip and a conductor. The chip includes a substrate and a plurality of contact portions arranged on the substrate. The plurality of contact portions include a front contact portion arranged on one side of the substrate and a back contact portion arranged on the other side of the substrate. In this way, the risk of the chip being short-circuited can be effectively reduced.

### CROSS-REFERENCE TO THE RELATED APPLICATIONS

This application is a continuation-in-part application of International Application No. PCT/CN2023/114326, filed on Aug. 22, 2023, which is based upon and claims priorities to Chinese Patent Application No. 202222217229.3, filed on Aug. 22, 2022; Chinese Patent Application No. 202222228069.2, filed on Aug. 23, 2022; Chinese Patent Application No. 202222295294.8, filed on Aug. 29, 2022; Chinese Patent Application No. 202322496455.4, filed on Sep. 13, 2023; and Chinese Patent Application No. 202420550005.0, filed on Mar. 20, 2024, the entire contents of which are incorporated herein by reference.

### TECHNICAL FIELD

The present invention relates to the field of imaging, and more particularly, to an imaging material box detachably installed in an imaging device and a chip assembly installed in the imaging material box.

### BACKGROUND

Conventional imaging devices include laser printers, copiers, ink-jet printers, and the like. The imaging devices are each provided with a box for containing an imaging material. The imaging materials are different depending on the type of the imaging device. For example, when the imaging device is a laser printer, the imaging material is toner. When the imaging device is an ink-jet printer, the imaging material is ink.

Generally, in order to establish a communication connection between the box and the imaging device, a chip assembly is installed on the box, and a contact portion of the chip assembly is in contact with a stylus of the imaging device when the box is installed to a predetermined position of the imaging device. The conventional chip assembly includes a substrate and contact portions arranged on the substrate. The contact portions are arranged in one or more rows, and the contact portions in the same row are centrosymmetric about a line connecting the two outermost contact portions in this row.

A plurality of contact portions of the conventional chip are arranged on the same side of the same substrate. In the limited surface area of the substrate, the arrangement design of these contact portions will be greatly limited. In addition, the densely arranged contact portions are easily short-circuited by dust/toner particles/ink falling on the surface of the substrate, thus damaging the chip.

### SUMMARY

The present invention provides a chip assembly and an imaging material box, so as to reduce the risk of a contact portion of a chip being short-circuited. The specific solution is as follows.

The chip assembly is configured to be installed in the imaging material box. The imaging material box is detachably installed on an imaging device provided with a stylus. The chip assembly includes a chip and a conductor. The chip includes a substrate and a plurality of contact portions arranged on the substrate. The plurality of contact portions include a front contact portion arranged on one side of the substrate and a back contact portion arranged on the other side of the substrate. The front contact portion is configured to be in contact with the stylus, and the back contact portion is electrically connected to the stylus through the conductor.

In an implementation, one side of the substrate is opposite to the other side.

In an implementation, the back contact portion is arranged on a third side of the substrate. The third side is a surface extending in a thickness direction of the substrate.

In an implementation, the imaging device is provided with a device-side terminal for electric connection with the stylus. The conductor includes a first conductive member and a second conductive member electrically connected to each other. One end of the first conductive member is in contact with the back contact portion and the other end of the first conductive member is in contact with the second conductive member. The second conductive member is located in front of the substrate and is configured to be in contact with the device-side terminal or the stylus.

In an implementation, at least one contact portion is arranged higher than other contact portions.

In an implementation, the conductor is in contact with the stylus to form the front contact portion on the conductor. A height difference is formed between at least one front contact portion and other front contact portions in the chip assembly.

In an implementation, the substrate includes a first sub-substrate and a second sub-substrate formed separately. The contact portions include a first sub-contact portion arranged on the first sub-substrate and a second sub-contact portion arranged on the second sub-substrate. The back contact portion is the first sub-contact portion or the second sub-contact portion. The first sub-substrate and the second sub-substrate are movable relatively.

The present invention further provides a chip assembly configured to be installed in the imaging material box. The imaging material box is detachably installed on an imaging device provided with a stylus. The chip assembly includes a chip and a conductor. The chip includes a substrate and a plurality of contact portions arranged on the substrate. The plurality of contact portions include: a front contact portion, configured to be directly electrically connected to the stylus; and a back contact portion, not arranged on the same side as the front contact portion. One end of the conductor is configured to be in contact with the back contact portion and the other end of the conductor is configured to be in contact with the stylus.

In an implementation, at least one contact portion is arranged higher than other contact portions.

In an implementation, the conductor is in contact with the stylus to form the front contact portion on the conductor. A height difference is formed between at least one contact portion and the other contact portions in the chip assembly.

In an implementation, the imaging device is provided with a device-side terminal for electric connection with the stylus. The conductor includes a first conductive member and a second conductive member electrically connected to each other. One end of the first conductive member is in contact with the back contact portion and the other end of the first conductive member is in contact with the second conductive member.

In an implementation, the conductor includes a front conductive member and a back conductive member electrically connected to each other. The front conductive member is configured to be electrically connected to the stylus, and the back conductive member is configured to be electrically connected to the back contact portion. The substrate is provided with an exposure hole for allowing exposure of the front conductive member, and the front conductive member extends beyond the surface provided with the front contact portion.

In an implementation, the conductor includes a front conductive member and a back conductive member electrically connected to each other. The front conductive member is configured to be electrically connected to the stylus, and the back conductive member is configured to be electrically connected to the back contact portion. The substrate is provided with an exposure hole for allowing exposure of the front conductive member, and the front conductive member extends beyond the surface provided with the front contact portion.

In an implementation, at least one contact portion is in contact with the side surface of the stylus.

In an implementation, at least one contact portion clamps the stylus.

In an implementation, at least one contact portion is formed as a clamping terminal for clamping the stylus. The clamping terminal is electrically connected to the conductor.

In an implementation, at least one contact portion is formed as a clamping terminal for clamping the stylus. The clamping terminal is a part of the conductor.

The present invention further provides an imaging material box, including a housing and an imaging material discharge portion arranged on the housing. The housing is configured to contain an imaging material. The imaging material box also includes the chip assembly as described above. The chip assembly is arranged on the housing.

### BRIEF DESCRIPTION OF THE DRAWINGS

FIG. 1A is a perspective view of an imaging material box according to the present invention.

FIG. 1B is a perspective view of a stylus arranged in an imaging device to which the imaging material box according to the present invention is applied.

FIG. 1C is a schematic diagram of a relative position between the stylus and the imaging material box after the imaging material box according to the present invention is installed to the imaging device.

FIG. 2 is a side view of a chip assembly according to Embodiment 1 of the present invention when viewed in a direction perpendicular to a chip substrate after being installed to an imaging material box.

FIG. 3 is a perspective front view of a chip according to Embodiment 2 of the present invention.

FIG. 4 is a perspective front view of a chip according to Embodiment 2 of the present invention.

FIG. 5 is a state diagram of a chip assembly according to Embodiment 2 of the present invention after being separated from a housing of an imaging material box.

FIG. 6 is a side view of a chip assembly according to Embodiment 3 of the present invention when viewed in a direction perpendicular to a chip substrate after being installed to an imaging material box.

FIG. 7 is a state diagram of a chip assembly according to Embodiment 4 of the present invention after being separated from a housing.

FIG. 8A is a side view of a chip assembly according to Embodiment 4 of the present invention in which a first chip is at a first position when viewed in a direction perpendicular to a chip substrate.

FIG. 8B is a side view of a chip assembly according to Embodiment 4 of the present invention in which a first chip is at a second position when viewed in a direction perpendicular to a chip substrate.

FIG. 9 is a side view of a chip assembly according to Embodiment 5 of the present invention.

FIG. 10 is a perspective view of a chip assembly according to Embodiment 6 of the present invention at a first position.

FIG. 11 is a perspective view of a chip assembly according to Embodiment 7 of the present invention at a first position.

FIG. 12A is an exploded view of a chip assembly according to Embodiment 8 of the present invention after being separated from a housing.

FIG. 12B is a perspective view of a chip assembly according to Embodiment 8 of the present invention when being in contact with a stylus assembly.

FIG. 13A is an exploded view of a chip assembly according to Embodiment 9 of the present invention after being separated from a housing.

FIG. 13B is a perspective view of a chip assembly according to Embodiment 9 of the present invention when being in contact with a stylus assembly.

FIG. 14 is a perspective view of a chip assembly according to Embodiment 10 of the present invention when being in contact with a stylus assembly.

FIG. 15 is a perspective view of a chip assembly according to Embodiment 11 of the present invention when being in contact with a stylus assembly.

FIG. 16 is a state diagram of an imaging material box according to the present invention separated from an imaging material box containing portion in an imaging device to which the imaging material box is applied.

FIG. 17 is a state diagram of a chip assembly according to Embodiment 12 of the present invention after being separated from a housing of an imaging material box.

FIG. 18 is a perspective view of some components in a chip assembly according to Embodiment 12 of the present invention.

FIG. 19 is a side view of an imaging material box provided with a chip assembly according to Embodiment 12 of the present invention when viewed in a y direction after being installed to an imaging device.

FIG. 20 is a cross-sectional view of the imaging material box and the imaging device of FIG. 19 sectioned in a plane perpendicular to a y direction and passing through a contact position between a contact portion and a corresponding stylus.

FIG. 21A and FIG. 21B are exploded views of a chip in a chip assembly according to Embodiment 13 of the present invention after being separated from an ink box housing.

FIG. 21C is a schematic diagram of a chip assembly according to Embodiment 13 of the present invention when viewed along a y direction.

FIG. 21D is a schematic diagram of a chip assembly according to Embodiment 13 of the present invention when viewed along an x direction.

FIG. 22A to FIG. 22C are schematic diagrams of an internal structure of an ink box according to Embodiment 13 of the present invention.

FIG. 22D is a perspective view of an ink box according to Embodiment 13 of the present invention when viewed from another perspective.

### DETAILED DESCRIPTION OF THE EMBODIMENTS

Embodiments of the present invention are described in detail with reference to the accompanying drawings.

### [Imaging Material Box]

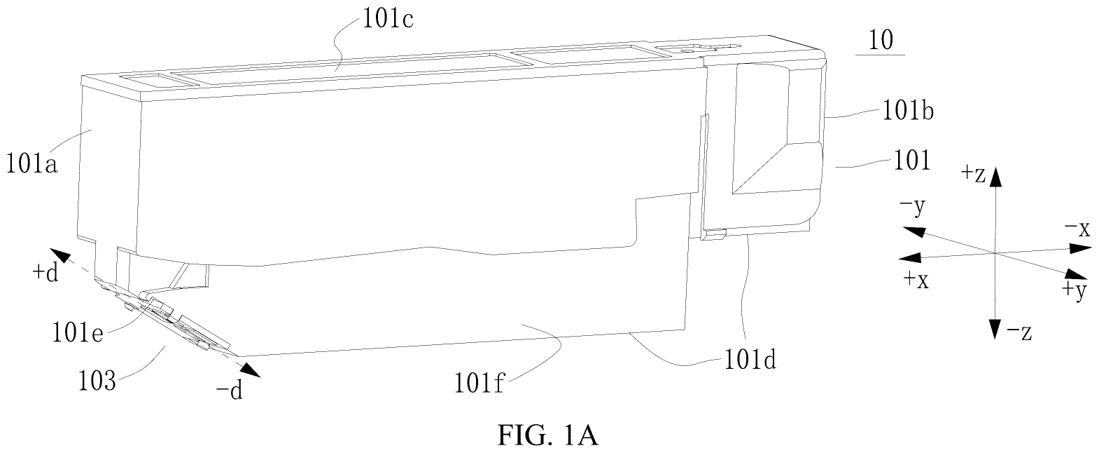

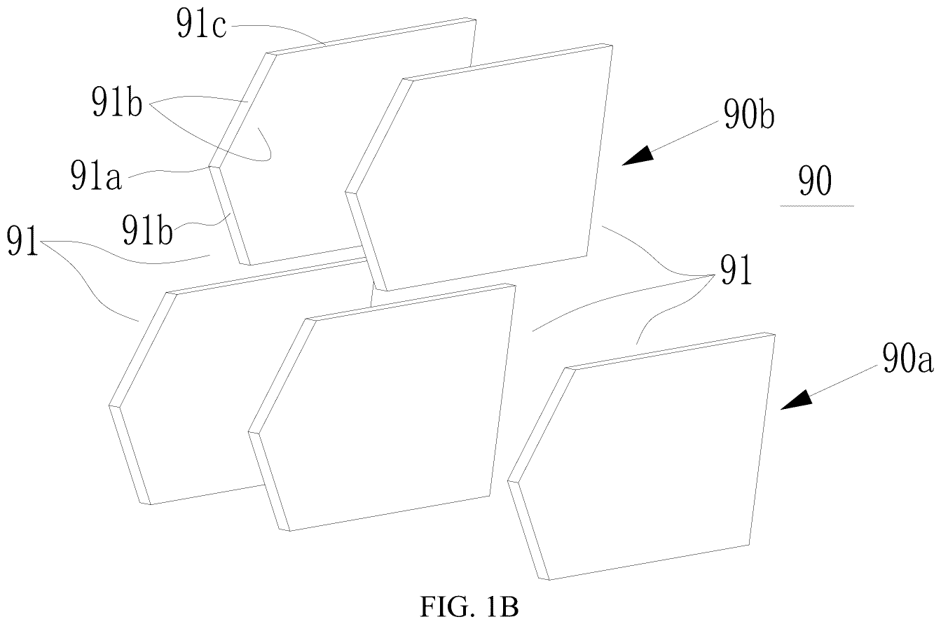

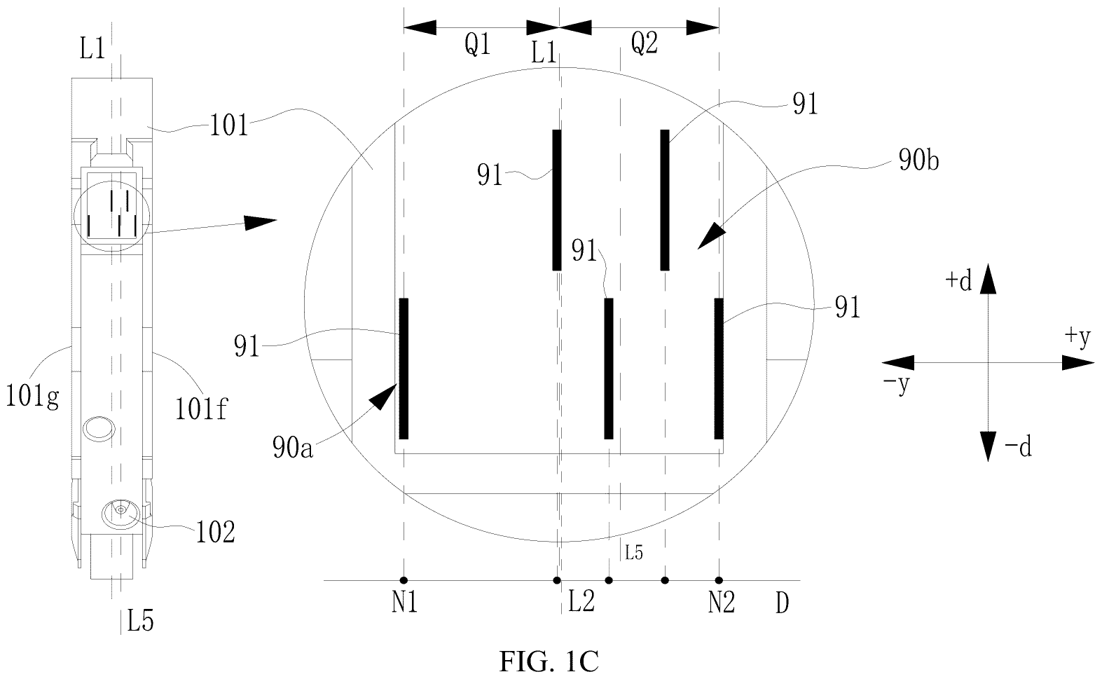

FIG. 1A is a perspective view of an imaging material box according to the present invention. FIG. 1B is a perspective view of a stylus arranged in an imaging device to which the imaging material box according to the present invention is applied. FIG. 1C is a schematic diagram of a relative position between the stylus and the imaging material box after the imaging material box according to the present invention is installed to the imaging device.

As described in the Background, the type of an imaging material contained in an imaging material box 10 is different depending on the type of an imaging device. The imaging material may be toner, and in this case, the imaging material box is a processing box or a powder cartridge. The imaging material may alternatively be ink, and in this case, the imaging material box is an ink box. However, a chip assembly 103 described below is applicable regardless of the type of the imaging material.

In order to make the following description clearer, based on the posture of an imaging material box when a user installs the imaging material box, the front of the sight of the user is defined as a +x direction, the rear of the sight of the user is defined as a −x direction, the top of the sight of the user is defined as a +z direction, the bottom of the sight of the user is defined as a −z direction, the left of the sight of the user is defined as a +y direction, and the right of the sight of the user is defined as a −y direction. The x direction, the y direction, and the z direction intersect. Preferably, the x direction, the y direction, and the z direction are perpendicular to each other. Generally, based on the installation posture of the imaging material box 10, a length direction of the imaging material box 10 is the x direction, a width direction is the y direction, and a height direction is the z direction. Specifically, a gravity direction of the imaging material box is the −z direction, and the opposite direction is the +z direction. More specifically, the direction may be seen in FIG. 1A.

The imaging material box will be described below as an ink box.

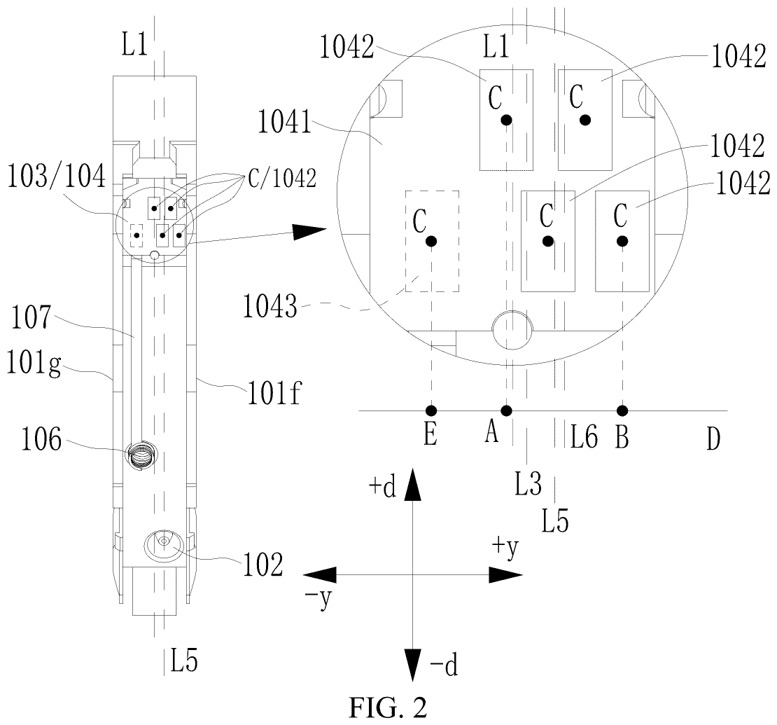

As shown in the figure, the ink box 10 includes a housing 101 containing ink, an ink discharge portion 102 (imaging material discharge portion) arranged on the housing, and a chip assembly 103. The housing has a front side wall 101a facing forward, a rear side wall 101b facing rearward, an upper side wall 101c facing upward, a lower side wall 101d facing downward, a left side wall 101f facing leftward, and a right side wall 101g facing rightward (as shown in FIG. 2). The front side wall 101a and the rear side wall 101b face in the x direction. The upper side wall 101c and the lower side wall 101d face in the z direction. The left side wall 101f and the right side wall 101g face in the y direction. A cavity for containing ink is defined at least by the front side wall 101a, the rear side wall 101b, the upper side wall 101c, the lower side wall 101d, the left side wall 101f, and the right side wall 101g.

The chip assembly 103 may be arranged on any one of the side walls of the housing 101, or an inclined side wall 101e inclined to the z direction is formed between the front side wall 101a and the lower side wall 101d. At least a part of the chip assembly 103 is opposite to the inclined side wall 101e. Preferably, the chip assembly 103 is arranged on the inclined side wall 101e.

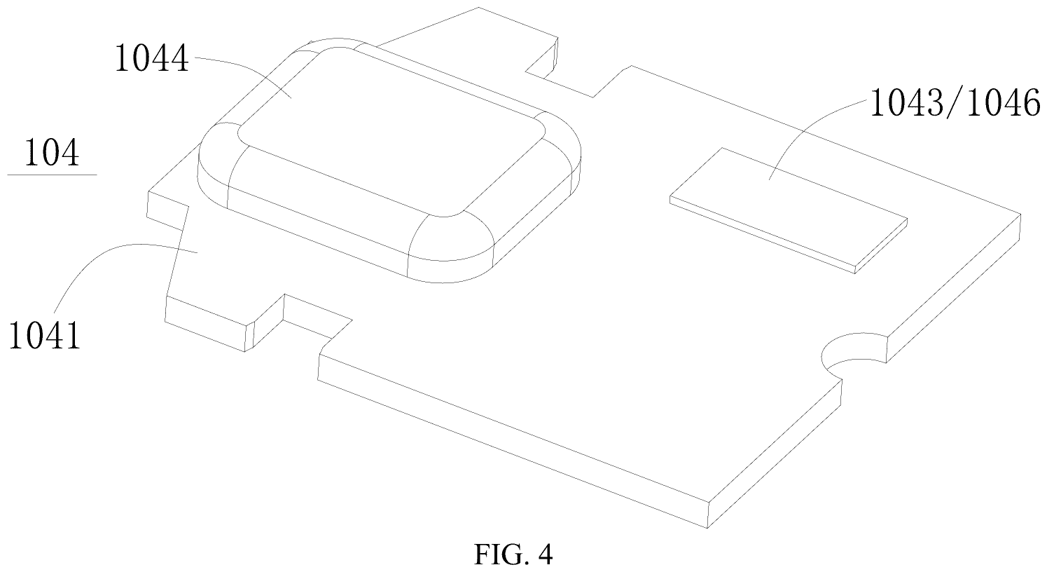

The chip assembly 103 includes at least a chip 104. As shown in the figure, the chip 104 includes a substrate 1041, a memory 1044 (as shown in FIG. 4), and at least one contact portion 1042/1043. Typically, the memory 1044 and the contact portion 1042 are both arranged on the substrate 1041. The memory 1044 and the contact portion 1042 are electrically connected, may be arranged on the same side of the substrate 1041, and may be respectively arranged on both sides of the substrate 1041. Alternatively, one of the memory 1044 and the contact portion 1042 is arranged on the substrate 1041 and the other is arranged outside the substrate 1041, but the memory 1044 and the contact portion 1042 are connected by wires. For ease of understanding and explanation, in the chip 104 described below, both the memory 1044 and the contact portion 1042 are arranged on the substrate 1041. Preferably, the chip is installed on the inclined side wall 101e.

A stylus assembly 90 located in the imaging device includes a plurality of styli 91. The arrangement of the contact portions 1042 in contact with the plurality of styli 91 in the chip assembly 103 is the same as that of the plurality of styli 91 as a whole. As shown in FIG. 1C, a region is defined in a direction parallel to the d direction and by two outermost straight lines of the substrate 1041. Projection points of contact points C of the two outermost contact portions located in the y direction and the corresponding styli on a plane including the y direction and the d direction and in a straight line D parallel to the y direction are respectively N1 and N2. A center line of the line segment N1N2 is L2. In the y direction, the region is divided into a first region Q1 and a second region Q2 adjacent thereto by the center line L2. In the y direction, the number of styli/contact portions in the first region Q1 is different from the number of styli/contact portions in the second region Q2. Hereinafter, the styli located in the first region Q1 are referred to as a first group of styli 90a, the styli located in the second region Q2 are referred to as a second group of styli 90b, and the number of styli in the first group of styli 90a is different from the number of styli in the second group of styli 90b. Each stylus 91 has a contact end 91a and a side surface 91b adjacent to the contact end 91a. The contact end 91a may be formed as any one of a point/line/surface. Preferably, the contact end 91a is formed as a tapered tip. The side surface 91b is a surface adjacent to the tapered tip. A distal surface 91c is adjacent to the side surface 91b.

In some embodiments, a center line L5 passing through the center of the ink discharge portion 102 in the d direction coincides with a center line L1 of the ink box 10 in the y direction. That is, the ink discharge portion 102 is arranged at the middle position of the housing 101 in the y direction. In this case, a relative position between the stylus assembly 90 and the center line L5 is the same as a relative position between the stylus assembly 90 and the center line L1.

In other embodiments, the center line L5 does not coincide with the center line L1. As shown in FIG. 1C, the center line L5 is closer to the left side wall 101f or the right side wall 101g of the housing 101 in the y direction than the center line L1. In this way, the number of styli/contact portions of the chip assembly 103 on both sides of the center line L5 is also different, and the probability of styli/contact portions of the chip assembly arranged further away from the center line L5 being contaminated by ink leaked from the ink discharge portion 102 is reduced. Accordingly, the risk of the chip being short-circuited is reduced.

Further, the center line L2 of the line segment N1N2 is configured so as not to coincide with the center line L1 or with the center line L5. The number of styli located on both sides of the center line L2 in the y direction is different, whereby the risk of the chip being short-circuited is reduced. Even if the imaging device shakes greatly, the shaking amplitude of the stylus can be reduced, thereby ensuring that the stylus is kept in good contact with the contact portion of the chip assembly 103.

### [Chip Assembly]

### Embodiment 1

FIG. 2 is a side view of a chip assembly according to Embodiment 1 of the present invention when viewed in a direction perpendicular to a chip substrate after being installed to an imaging material box.

As described above, the inclined side wall 101e is inclined to the z direction. When viewed in a direction perpendicular to the substrate 1041, the up-down direction of the sight will no longer be the z direction, but the d direction shown in FIG. 2. The d direction is perpendicular to the y direction, and the d direction also intersects the z direction and the x direction at a non-perpendicular angle. In other embodiments, the d direction will be the same as the z direction when the housing 101 is not provided with the inclined side wall 101e, or the chip 104 is arranged on the front side wall 101a, and the d direction will be the same as the x direction when the chip 104 is arranged on the lower side wall 101d.

As shown in FIG. 2 the center line L1 is perpendicular to the y direction and divides the housing 101 into two parts symmetrical in the y direction. That is, the straight line L1 is the center line of the housing 101 in the y direction. A plurality of contact portions 1042 of the chip 104 are provided, and all of the contact portions 1042 are located on the same side of the substrate 1041. Each contact portion forms a contact point C with the stylus of the imaging device. In the y direction, the plurality of contact portions 1042 are staggered. In the d direction, the plurality of contact portions are arranged in multiple rows. The straight line D is parallel to the y direction. Projection points of the contact point C at the end of the +y direction and the contact point C at the end of the −y direction on the plane passing through the y direction and the d direction and in the straight line D are respectively B and A. A center line of the line segment BA is L6.

In this embodiment, the center line L1 does not coincide with the center line L6, and the plurality of contact portions 1042/contact points C are configured so as not to be symmetrical about the center line L1 in the y direction as a whole. In other words, all or most of the plurality of contact portions 1042/contact points C are arranged on one side of the center line L1, or the number of contact portions 1042/contact points C on one side of the center line L1 is greater than the number of contact portions 1042/contact points C on the other side of the center line L1. The center line L6 also does not coincide with the center line L5. In this way, in the y direction, at least one contact portion 1042/contact point C is arranged away from the center line L5/L6, and ink leaked from the ink discharge portion 102 is less likely to contaminate the at least one contact portion 1042.

The chip 104 has the following beneficial effects:

(1) After the ink box 10 having such a chip 104 is installed to the imaging device, even if the device shakes greatly, the shaking amplitude of the chip 104 can be reduced, the shaking amplitude of the stylus is correspondingly reduced, and the superposition value of the two shaking amplitudes is also small. Specifically, the contact point C and the stylus still maintain good contact.

(2) In the y direction, when the center line of the substrate 1041 coincides with the center line L1, the area used on one side of the chip 104 is smaller than the area used on the other side with the center line L1 as the boundary. Then other arrangements may be performed on the side having a larger use area according to the design requirements. For example, a fixing portion for fixing the chip is arranged on the side, or a storage portion 1044 is arranged on the side. Therefore, the design freedom of the chip 104 is greatly improved.

(3) The center line L1 does not coincide with the center line L6. In the y direction, the center line L6 will be closer to one side of the substrate 1041 than the center line L1, whereby the contact portions 1042/contact points C are more concentrated between the side of the substrate 1041 close to the center line L6 and the center line L6 in the y direction, while more structures or components can be arranged between the side of the substrate 1041 far away from the center line L6 and the center line L6. In addition, in the y direction, the contact portions 1042/contact points C far away from the center line L6 are less likely to be contaminated by ink.

### Embodiment 2

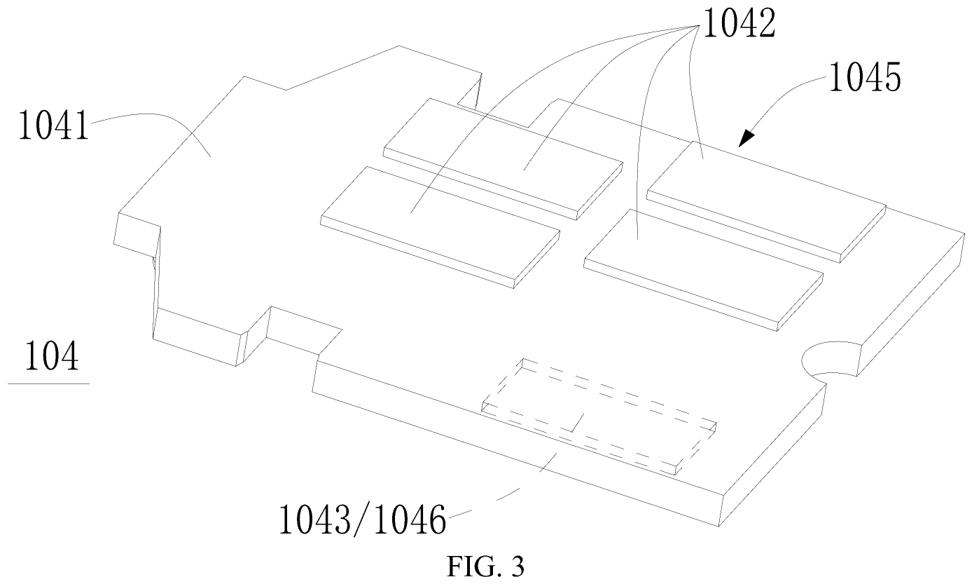

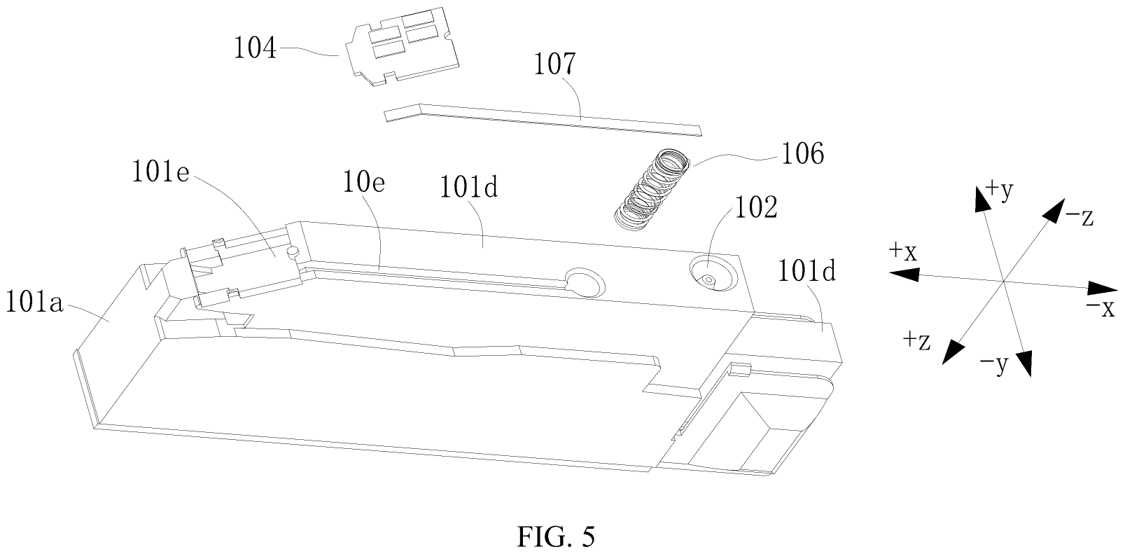

FIG. 3 is a perspective front view of a chip according to Embodiment 2 of the present invention. FIG. 4 is a perspective front view of a chip according to Embodiment 2 of the present invention. FIG. 5 is a state diagram of a chip assembly according to Embodiment 2 of the present invention after being separated from a housing of an imaging material box.

This embodiment is different from Embodiment 1 in that some contact portions 1042 are arranged on the other side of the substrate. Therefore, the plurality of contact portions 1042 may be divided into a first group of contact portions 1045 and a second group of contact portions 1046. The first group of contact portions 1045 is located on one side (the first side) of the substrate 1041, and the second group of contact portions 1046 is located on the other side (the second side) of the substrate 1041. Hereinafter, the second group of contact portions 1046 arranged on the other side of the substrate 1041 includes one or more back contact portions 1043, and the first group of contact portions 1045 arranged on the side of the substrate 1041 includes one or more front contact portions 1042.

As shown in FIG. 3 and FIG. 4, the storage portion 1044 is arranged on one side of the substrate 1041. A back contact section 1043 is arranged on the same side as the storage portion 1044. A plurality of front contact portions 1042 are arranged opposite to the storage portion 1044. The front contact portions 1042 and the back contact portion 1043 may be configured so as to protrude from the substrate 1041 by a predetermined height, and may coincide with the surface of the substrate 1041.

Specifically, the back contact portion 1043 may be any one of a power terminal and a grounding terminal. When a plurality of back contact portions 1043 are provided, both the power terminal and the grounding terminal may be configured as the back contact portions 1043. As shown in FIG. 5, the chip assembly 103 also includes a pushing member 106 and a conductor 107. One end of the conductor 107 is configured to be in contact with the back contact portion 1043, and the other end of the conductor is configured to be in contact with the pushing member 106. When the ink box 10 is installed to the imaging device, the pushing member 106 pushes the conductor 107 into contact with a component arranged at a corresponding position of the imaging device. That is, the stylus in contact with the back contact portions 1043 in the imaging device is different from the stylus in contact with the front contact portions 1042.

By arranging the contact portions as described above, the surface of the substrate 1041 may be fully utilized. Especially when the back contact portion 1043 is a grounding terminal, the back contact portion 1043 may be brought into contact with a corresponding component of the imaging device before the ink box 10 is installed to a predetermined position, thereby releasing static electricity carried on the chip 104 and preventing the chip 104 from being damaged by the static electricity. The conductor 107 may be preset to be in contact with the back contact portion 1043, or may be preset not to be in contact with the back contact portion 1043. However, the conductor 107 may be in contact with the back contact portion 1043 during the installation of the ink box 10.

Preferably, the conductor 107 is arranged on the lower side wall 101d. In this way, the contact between the conductor 107 and the corresponding stylus is more stable by the gravity of the ink box and the thrust of the pushing member 106. Further, the housing 101 is provided with an installation groove 10e in which the conductor 107 is placed. In this way, the installation position of the conductor 107 is precisely determined, and the contact of the conductor 107 with the back contact portion 1043 and the stylus is more stable.

As shown in FIG. 2 again, in the y direction, the back contact portion 1043 is arranged away from the front contact portion 1042. Projection points of the two outermost contact points C in the y direction on the plane passing through the y direction and the d direction and in the straight line D are respectively E and B. A center line of the line segment EB is L3. In this embodiment, in the y direction, regardless of whether the center line L1 coincides with the center line L3, the back contact portion 1043 is away from the front contact portion 1042, and the back contact portion 1043 is led out through the conductor 107, resulting in beneficial effects as described in Embodiment 1, which will not be described herein. For Embodiment 1, when the back contact portion 1043 and the front contact portion 1042 are arranged on the same side of the substrate 1041, relative positions between the center line L3 and the center lines L1 and L6 are not changed.

In Embodiment 1 and Embodiment 2, when the center line L5 passing through the ink discharge portion 102 does not coincide with the center line L1, the center line L6 and the center line L3 do not coincide with the center line L5, whereby the contact portions 1042/1043 or the contact points C away from the center line L5 in the y direction are likewise prevented from being easily contaminated by ink leaked from the ink discharge portion 102.

As the first side and the second side are opposite to each other, it can be understood that the back contact portion 1043 should not be limited to the side opposite to the front contact portion 1042, and the back contact portion 1043 may alternatively be arranged on another surface of the substrate 1041 as long as the back contact portion is not arranged on the same side as the front contact portion 1042. For example, the back contact portion 1043 is arranged on a third side between the first side and the second side, or the back contact portion is arranged on a surface different from both the first side and the second side.

### Embodiment 3

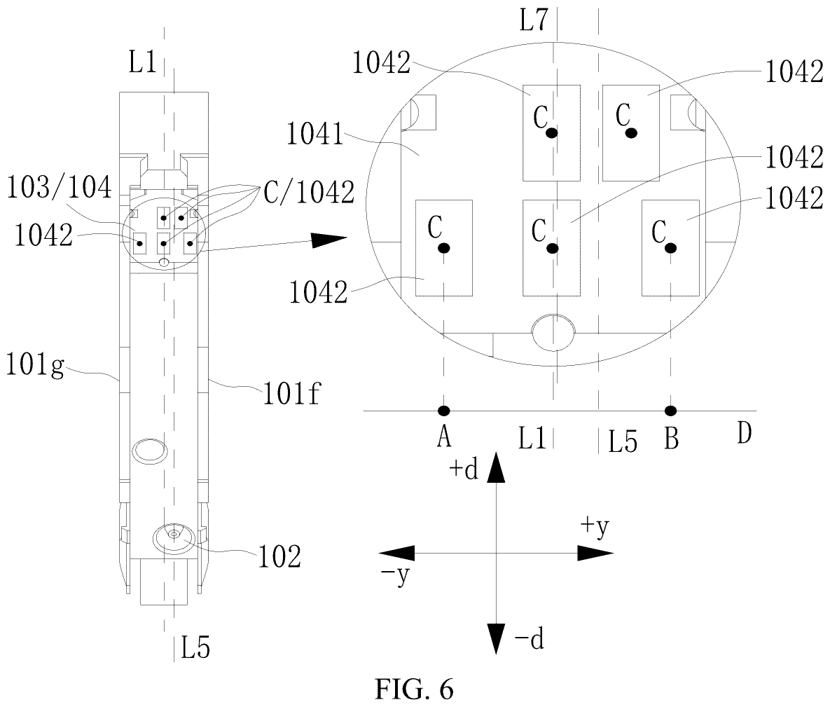

FIG. 6 is a side view of a chip assembly according to Embodiment 3 of the present invention when viewed in a direction perpendicular to a chip substrate after being installed to an imaging material box.

Different from Embodiments described above, the plurality of contact portions 1042 in this embodiment are configured such that at least two contact portions 1042 coincide in the d direction, and more specifically, at least two contact points C coincide in the d direction.

As shown in FIG. 6, projection points of the two outermost contact points C in the y direction on the plane including the y direction and the d direction and in the straight line D are respectively A and B. A center line of the line segment AB is L7. The center line L1 does not coincide with the center line L7, resulting in beneficial effects as described in Embodiment 1, which will not be described herein.

In this embodiment, in the y direction, the center line L5 passing through the ink discharge portion 102 does not coincide with the center line L7, whereby the contact portions 1042/1043 or the contact points C away from the center line L5 in the y direction are likewise prevented from being easily contaminated by ink leaked from the ink discharge portion 102.

### Embodiment 4

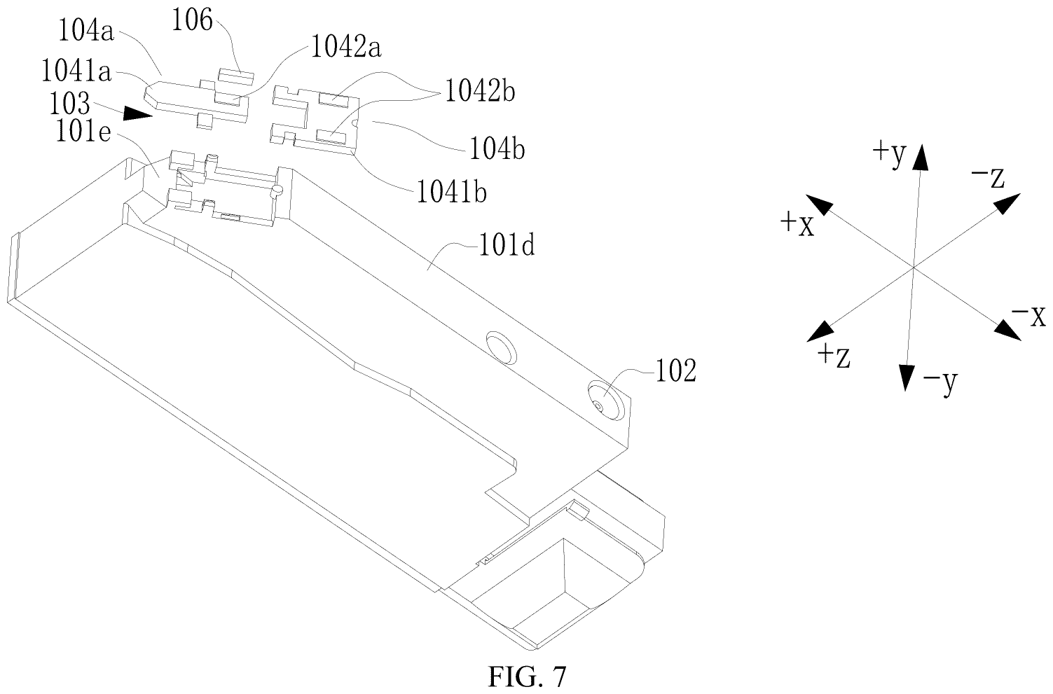

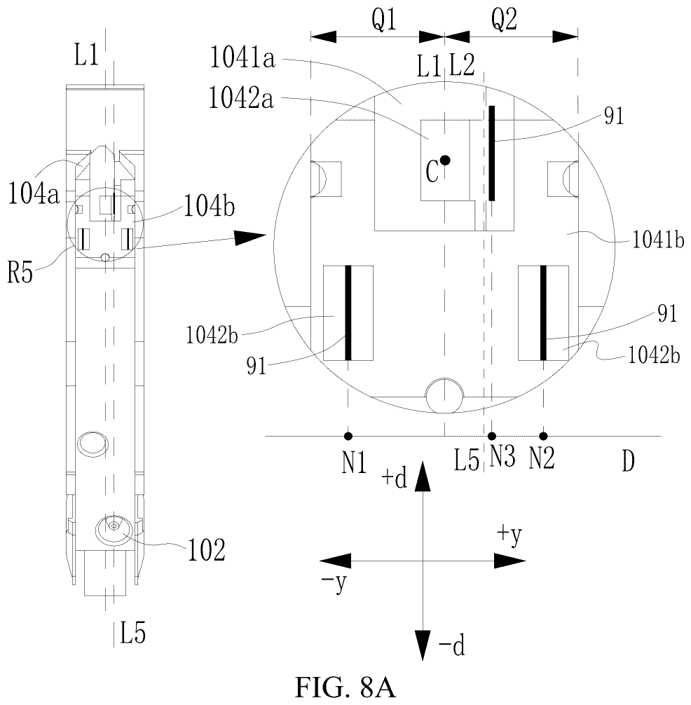

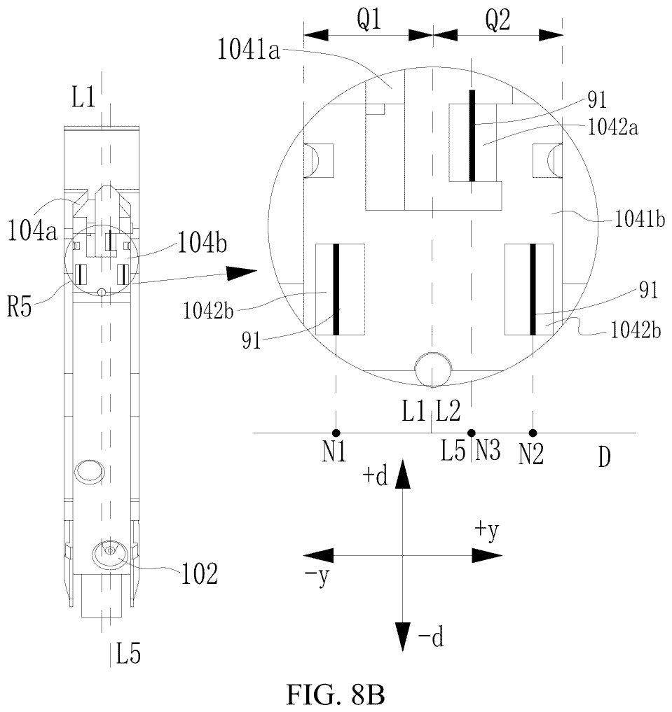

FIG. 7 is a state diagram of a chip assembly according to Embodiment 4 of the present invention after being separated from a housing. FIG. 8A is a side view of a chip assembly according to Embodiment 4 of the present invention in which a first chip is at a first position when viewed in a direction perpendicular to a chip substrate. FIG. 8B is a side view of a chip assembly according to Embodiment 4 of the present invention in which a first chip is at a second position when viewed in a direction perpendicular to a chip substrate.

In this embodiment, the chip 104 located in the chip assembly 103 is configured to include a plurality of split components combined. As shown in FIG. 7, the chip 104 includes a first sub-chip 104a and a second sub-chip 104b movable relatively. The first sub-chip 104a and the second sub-chip 104b may be independent of each other. In this case, even if the first sub-chip 104a and the second sub-chip 104b are not combined, the first sub-chip and the second sub-chip may respectively perform the function of the chip. When the first sub-chip and the second sub-chip are combined, the function of the chip is still implemented. Therefore, after the first sub-chip 104a and the second sub-chip 104b are combined, the first sub-chip 104a and the second sub-chip 104b may be two independent components completely independent of each other or may be two components having a communication connection established. In other embodiments, the first sub-chip 104a and the second sub-chip 104b may alternatively be configured such that the function of the chip 104 may be performed only if the first sub-chip and the second sub-chip are combined with each other to form the chip 104 and a communication connection is established therebetween. The first sub-chip 104a and the second sub-chip 104b may be provided with a storage portion 1044 at the same time or only one of the first sub-chip and the second sub-chip may be provided with a storage portion 1044. As for the way in which the communication connection is established between the first sub-chip 104a and the second sub-chip 104b, the wire connection in the prior art and various wireless communication modes (for example, Bluetooth communication and near field communication) may be adopted.

As shown in FIG. 7 again, the first sub-chip 104a includes a first sub-substrate 1041a and at least one first sub-contact portion 1042a arranged on the first sub-substrate 1041a, and the second sub-chip 104b includes a second sub-substrate 1041b and a second sub-contact portion 1042b arranged on the second sub-substrate 1041b. The first sub-chip 104a and the second sub-chip 104b may be respectively provided with a storage portion or may share one storage portion. For convenience of description and understanding, the chip 104 described below is provided with a total of three contact portions including one first sub-contact portion 1042a and two second sub-contact portions 1042b. The back contact portion may be either the first sub-contact portion 1042a or the back contact portion 1042b.

Further, the chip assembly 103 also includes a pushing member 106 in contact with the first sub-chip 104a and/or the second sub-chip 104b. The pushing member 106 is configured to push one of the first sub-chip 104a and the second sub-chip 104b toward a first position described below. Hereinafter, the first sub-chip 104a is movable, and the second sub-chip 104b is fixed to the housing 101. Therefore, the pushing member 106 is in contact with the first sub-chip 104a.

As shown in FIG. 8A, for the stylus assembly 90, the styli (which may be referred to as outer styli) 91 respectively in contact with the two second sub-contact portions 1042b are located outermost in the y direction. Projection points of the two styli on the plane passing through the y direction and the d direction and in the straight line D are respectively N1 and N2. The center line L2 of the line segment N1N2 coincides with the center line L1. That is, the two outermost styli 91 are symmetrically arranged on both sides of the center line L1 in the y direction based on the center line L1. Projection points of the stylus 91 (which may be referred to as an intermediate stylus) in contact with the first sub-contact portion 1042a on the plane passing through the y direction and the d direction and in the straight line D are N3. N3 is located between N1 and N2, but the center line L1 does not pass through N3.

Similarly, in the y direction, the center line L1/L2 divides the region between the two outermost straight lines after the first sub-substrate 1041a and the second sub-substrate 1041b are combined into a first region Q1 and a second region Q2. When the center line L5 does not coincide with the center line L1, the number of styli located on both sides of the center line L5 is different in the y direction.

In this embodiment, the positions of the two second sub-contact portions 1042b relative to the center line L1 are the same as the positions of the two outer styli relative to the center line L1. That is, the two second sub-contact portions 1042b are symmetrically arranged on both sides of the center line L1 in the y direction.

Before the ink box 10 is installed, the intermediate stylus 91 is located in the second region Q2, the first sub-chip 104a is located at the first position, and the center line L1 passes through the contact point C at the first sub-contact portion 1042a. When viewed as a whole, the first sub-contact portion 1042a and the two second sub-contact portions 1042b are symmetrical about the center line L1 in the y direction, or the center line L1 does not pass through the contact point C. In this case, the contact point C is located in the −y direction of the center line L1/L2, and the contact point C may be considered to be located in the first region Q1.

With the installation of the ink box 10, the first sub-substrate 1041a starts to be touched by an external trigger member (which may be a side wall, a door cover, and the like in the imaging device, or a member installed on the housing) to move in the y direction. Specifically, the first sub-substrate 1041a/first sub-contact portion 1042a gradually approaches the intermediate stylus, and the pushing member 106 elastically deforms. As shown in FIG. 8B, when the ink box 10 reaches a predetermined installation position, the first sub-chip 104a reaches a second position. The first sub-contact portion 1042a moves from the first region Q1 to the second region Q2 and is in contact with the intermediate stylus 91. That is, the intermediate stylus 91 is in contact with the contact point C located at the first sub-contact portion 1042a. When the ink box 10 is removed from the predetermined installation position, the pushing member 106 releases an elastic force, and the first sub-chip 104a returns from the second position to the first position.

As can be seen from the above description, the first sub-contact portion 1042a is located in the first region Q1 before the ink box 10 reaches the predetermined installation position. During the installation process of the ink box 10, the first sub-contact portion 1042a moves from the first region Q1 to the second region Q2. Based on the ink box 10 being in a working state, the first sub-contact portion 1042a should originally be arranged in the second region Q2, but before the ink box 10 reaches the predetermined installation position, the first sub-contact portion 1042a is located in the first region Q1. When the ink box 10 reaches the predetermined installation position, the first sub-contact portion 1042a moves from the first region Q1 to the second region Q2. The first sub-chip 104a is configured to reciprocate between the first position and the second position relative to the housing 101/second sub-chip 104b in a direction parallel to or intersecting the y direction as long as the first sub-chip 104a can be displaced in the y direction. Further, the plurality of contact portions 1042 of the chip 104 are symmetrical about the center line L1 at the first position, and the plurality of contact portions 1042 of the chip 104 are asymmetrical about the center line L1 at the second position. Conversely, the second sub-chip 104b may alternatively be configured to reciprocate relative to the housing 101/first sub-chip 104b between the first position and the second position. Similarly, the plurality of contact portions 1042 of the chip 104 are symmetrical about the center line L1 at the first position, and the plurality of contact portions 1042 of the chip 104 are asymmetrical about the center line L1 at the second position.

Based on the above inventive concept, whether the first sub-chip 104a is configured to move relative to the second sub-chip 104b or the second sub-chip 104b is configured to move relative to the first sub-chip 104a, the relative position between the plurality of contact portions 1042 of the chip 104 may also be described as: the plurality of contact portions 1042 are symmetrical, at the first position, about a line perpendicular to the y direction through a contact point C formed on the contact portion in contact with the intermediate stylus, and the plurality of contact portions 1042 are asymmetrical, at the second position, about a line perpendicular to the y direction through a contact point C formed on the contact portion in contact with the intermediate stylus.

The chip 104 according to this embodiment has the following beneficial effects:

(1) Dust/impurities/ink droplets adhered to the first sub-chip 104a and/or the second sub-chip 104b will be shaken off by vibration generated during the relative movement of the first sub-chip 104a and the second sub-chip 104b, and the risk of short circuit between the plurality of contact portions 1042 is reduced.

(2) When the ink box 10 is not installed, there will be a certain gap/groove between the first sub-chip 104a and the second sub-chip 104b movable relatively, and the structure will assist in shaking off dust/impurities/ink droplets from the chip 104 faster.

(3) The plurality of contact portions 1042 are asymmetrical, at the second position, about the center line L1 or a straight line passing through the intermediate stylus and perpendicular to the y direction. In the y direction, at least one contact portion is located away from the other contact portions. That is, the plurality of contact portions are not centrally arranged and are not required to be arranged too densely. In this way, when impurities/ink droplets are in contact with the at least one contact portion, it is difficult for impurities/ink droplets to be in contact with other contact portions to cause short circuit of the chip 104.

(4) At the first position, at least one contact portion (first sub-contact portion 1042a) of the plurality of contact portions 1042 that should be located in the second region Q2 is actually located in the first region Q1. At the second position, the contact portion (first sub-contact portion 1042a) that should be located in the second region Q2 reaches the second region Q2 from the first region Q1, which can also prevent impurities/ink droplets from short-circuiting the chip 104.

(5) In combination with the beneficial effects (1), (3), and (4), even if the ink droplets are not all shaken off during the relative movement of the first sub-chip 104a and the second sub-chip 104b, the surface tension of the remaining ink droplets will be less than the surface tension of the ink droplets before being shaken off, and the ink droplets can also be prevented from connecting the two contact portions and short-circuiting.

(6) The beneficial effect is the same as the beneficial effect (1) of Embodiment 1.

### Embodiment 5

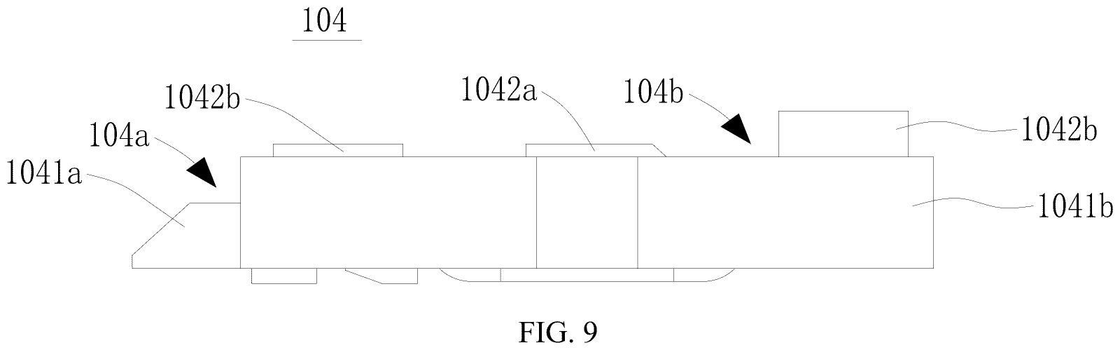

FIG. 9 is a side view of a chip assembly according to Embodiment 5 of the present invention.

This embodiment differs from Embodiment 4 in that the first sub-contact portion 1042a and the second sub-contact portion 1042b extend at different heights in an extending direction of the contact portion 1042. When the first sub-substrate 1041a and the second sub-substrate 1041b are flush, at least one contact portion protrudes higher. In this way, the contact portion and the corresponding stylus are also in closer contact. In addition, a height difference is formed between the contact portion protruding higher and another contact portion, and impurities or ink droplets are less likely to communicate the contact portions and cause short circuit.

In some embodiments, the first sub-substrate 1041a and the second sub-substrate 1041b may alternatively be integrally formed. In this case, at least one contact portion may also be arranged higher than other contact portions. For example, in the chip assembly 103 formed with five contact portions 1042, one of the contact portions may be arranged higher than the other four contact portions.

### Embodiment 6

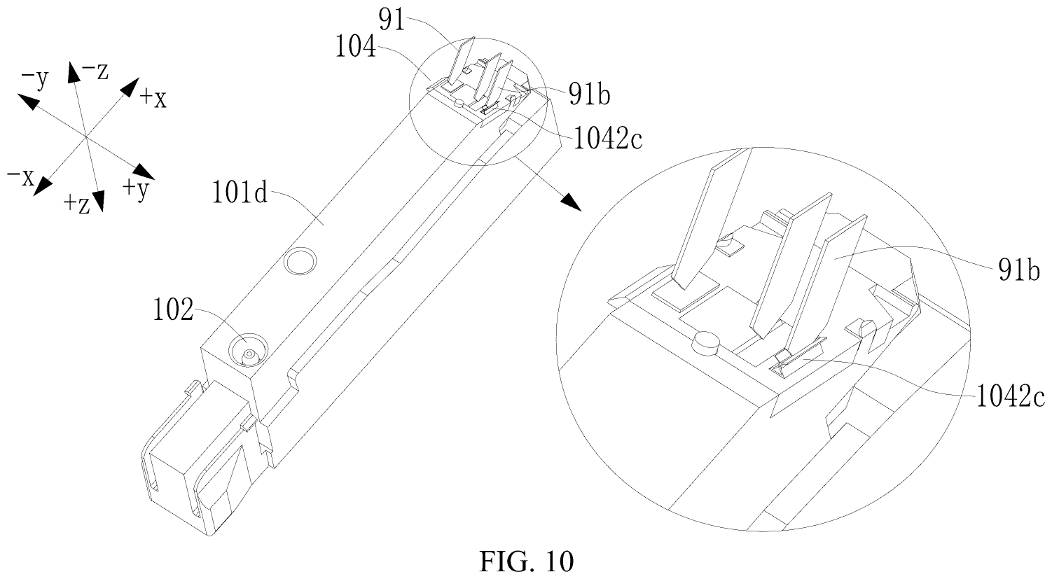

FIG. 10 is a perspective view of a chip assembly according to Embodiment 6 of the present invention at a first position.

In Embodiment 4 and Embodiment 5 described above, the contact portions 1042 are all configured to be in contact with the contact end 91a of the stylus. In this embodiment, at least one contact portion 1042 is configured to be in contact with the side surface 91b/distal surface 91c of the stylus. As shown in FIG. 10, the at least one contact portion 1042 is configured to clamp the stylus 91. In this way, the contact portion 1042 is in contact with the side surface 91b of the stylus 91. The contact portion for clamping the stylus 91 will be arranged higher than the other contact portions. That is, a height difference will be formed between the contact portion for clamping the stylus 91 and the other contact portions. The contact portion clamps the stylus, thereby improving the contact stability between the chip assembly 103 and the stylus. Even if the ink box 10 is deflected or shaken in the y direction, the contact portion and the stylus can still maintain good contact.

The above describes an embodiment in which a sub-substrate moves together with a sub-contact portion located on the sub-substrate. It is realizable that the object of the present invention can also be achieved when only the sub-contact portion moves. The movable sub-contact portion may be regarded as the first sub-chip or the second sub-chip.

The above embodiments also describe that at the first position, the plurality of contact portions 1042 are in a state of being symmetrical about the center line L1 or being symmetrical about a straight line passing through a contact point C formed on a contact portion in contact with the intermediate stylus and perpendicular to the y direction. At the second position, the plurality of contact portions 1042 are in a state of being asymmetrical about the center line L1 or being asymmetrical about the straight line passing through the contact point C formed on the contact portion in contact with the intermediate stylus and perpendicular to the y direction. However, at the first position, the plurality of contact portions 1042 may also be in a state of being asymmetrical about the center line L1 or being asymmetrical about the straight line passing through the contact point C formed on the contact portion in contact with the intermediate stylus and perpendicular to the y direction. For example, at the first position, the contact point C formed on the contact portion in contact with the intermediate stylus is located in the −y direction of the center line L1/L2. At the second position, the contact point C is located in the +y direction of the center line L1/L2. Based on the ink box 10 being in a working state, so long as the contact portion originally arranged in the first region Q1 or the second region Q2 can be moved from a position beyond an arranged region to a position within the arranged region, for example, the first sub-contact portion 1042a in Embodiment 4. Further, the contact portion to be moved is preferably at least one contact portion between the two outermost contact portions in the y direction or, for example, the first sub-contact portion 1042a in Embodiment 4. Furthermore, the first position of the movable contact portion may be in the first region Q1, and may alternatively be in a region other than the first region Q1 and the second region Q2.

In a deformable embodiment, the first sub-chip 104a and the second sub-chip 104b may alternatively be configured such that the first sub-substrate 1041a and the second sub-substrate 1041b at least partially overlap or the first sub-contact portion 1042a and the second sub-contact portion 1042b at least partially overlap or contact points at the first sub-contact portion 1042a and contact points at the second sub-contact portion 1042b overlap in a direction perpendicular to both the y direction and the d direction at the first position, and the contact points at the first sub-contact portion 1042a and the contact points at the second sub-contact portion 1042b no longer overlap at least at the second position.

In the above embodiments, when three contact portions are provided, at least one of a data terminal and a clock terminal is located in the first region at the first position, at least one of the data terminal and the clock terminal is movable from the first region Q1 to the second region Q2 at the second position, and the data terminal is configured to detect whether there is a short circuit between the terminal and any one of the data terminal and the clock terminal.

When five contact portions are provided, the five contact portions are respectively a first terminal 10421 (data terminal cpd), a second terminal 10422 (clock terminal cpc), a third terminal 10423 (reset terminal cpr), a fourth terminal 10424 (power terminal cpvd), and a fifth terminal 10425 (grounding terminal cpvs). In the y direction, the first terminal 10421 and the fifth terminal 10425 are respectively located outermost. At least one of the first terminal 10421 (data terminal cpd), the second terminal 10422 (clock terminal cpc), the third terminal 10423 (reset terminal cpr), and the fourth terminal 10424 (power terminal cpvd) is located in the first region at the first position, at least one of the first terminal 10421 (data terminal cpd), the second terminal 10422 (clock terminal cpc), the third terminal 10423 (reset terminal cpr), and the fourth terminal 10424 (power terminal cpvd) is movable from the first region Q1 to the second region Q2 at the second position, and the first terminal 10421 (data terminal cpd) is configured to detect whether there is a short circuit between the terminal and any one of the second terminal 10422 (clock terminal cpc), the third terminal 10423 (reset terminal cpr), and the fourth terminal 10424 (power terminal cpvd). Preferably, the terminals (second terminal 10422, third terminal 10423, and fourth terminal 10425) located between the two outermost terminals (first terminal 10421 and fifth terminal 10425) are configured to be movable between the first position and the second position.

As described above, the contact point C/C1 in contact with the stylus in the imaging material box 10 is configured to be asymmetrical in the y direction. Even if the imaging device shakes greatly, the shaking amplitude of the chip assembly 103/contact point C/C1 and the stylus is reduced. Therefore, the contact point C/C1 and the stylus can still maintain good contact.

### Embodiment 7

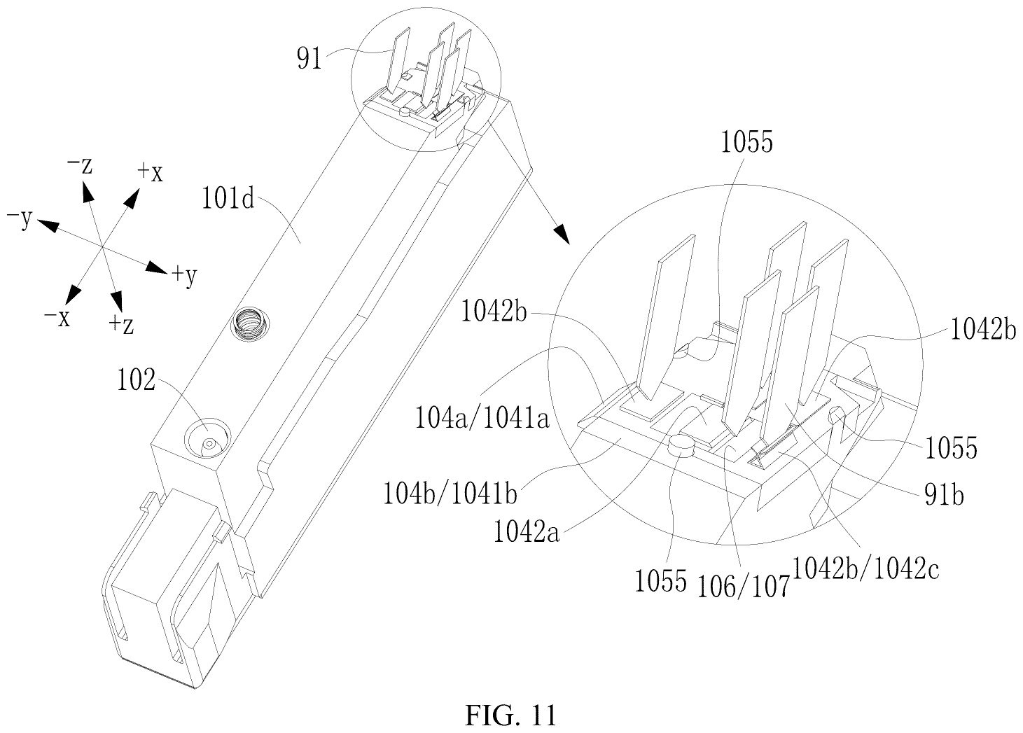

FIG. 11 is a perspective view of a chip assembly according to Embodiment 7 of the present invention at a first position.

In Embodiment 6, when five contact portions 1042 are provided, one of the terminals is movable between the first region and the second region. Alternatively, one of the terminals is movable between the first position and the second position. As shown in FIG. 11 of this embodiment, the movable terminal (one of the first sub-contact portions 1042a) is arranged on the first sub-chip 104a, and the pushing member 106 abuts against the first sub-chip 104a for pushing the first sub-chip 104a to the first position. In addition, one of the second sub-contact portions 1042b (clamping terminal 1042c) is also configured to clamp the corresponding stylus 91. The clamped part is at least any one of the side surface 91b and the distal surface 91c of the stylus 91. Similarly, the chip assembly 103 in this embodiment also has the beneficial effects of Embodiment 4.

Preferably, the clamping terminal 1042c and the memory 1044 are electrically connected through the conductor 107. In this way, a line for electrically connecting the clamping terminal 1042c to the memory 1044 is not required inside the substrate 1041, thereby simplifying the structure of the chip 4.

Further, the contact portion in this embodiment may alternatively be configured to include the front contact portion 1042 and the back contact portion 1043 as described above. As shown in FIG. 11, the chip assembly also includes the conductor 107. One end of the conductor 107 is configured to be in contact with the back contact portion 1043. The conductor 107 is in contact with the corresponding stylus when the ink box 10 is installed to the imaging device.

In some implementations, the pushing member 106 may alternatively be retained. The conductor 107 can be in stable contact with the back contact portion 1043 and/or the stylus under the pushing action of the pushing member 106.

As shown in FIG. 11, the chip assembly 103 also includes at least one positioning portion 1055. The positioning portion 1055 may be arranged on the inclined side wall 101e or at another suitable position. The chip 104 is positioned by the positioning portion 1055. For example, the positioning portion 1055 is configured as a column. After the chip 104 is positioned, the positioning portion 1055 is deformed by heat welding to make the chip 104 fixed. Alternatively, the positioning portion 1055 is configured as a protrusion with barbs, whereby the chip 104 is fixed while being positioned by the positioning portion 1055.

### Embodiment 8

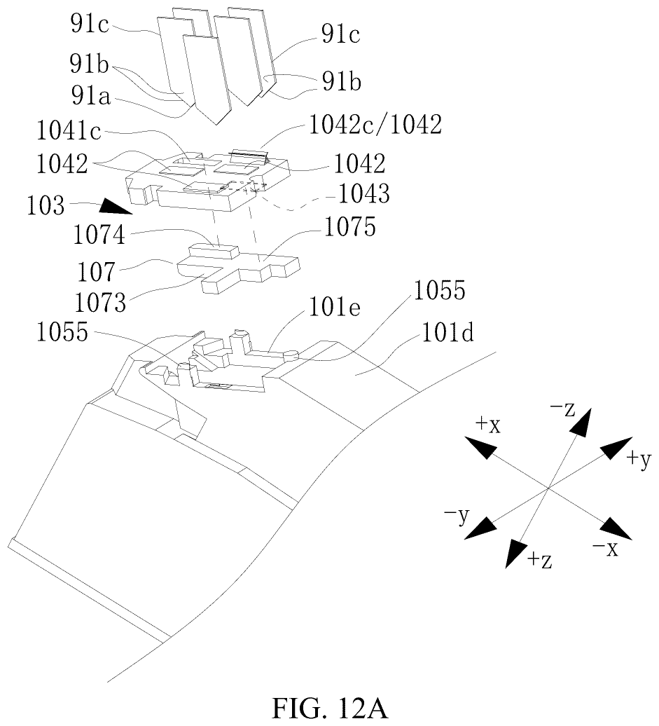

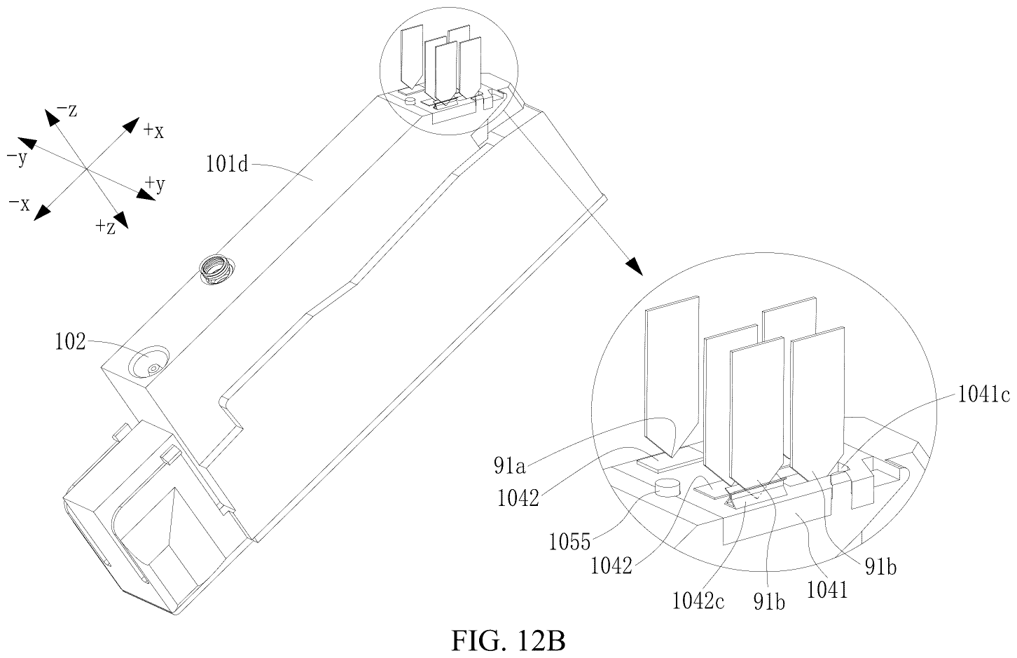

FIG. 12A is an exploded view of a chip assembly according to Embodiment 8 of the present invention after being separated from a housing. FIG. 12B is a perspective view of a chip assembly according to Embodiment 8 of the present invention when being in contact with a stylus assembly.

Different from Embodiment 7, in this embodiment, one chip substrate 1041 is provided, but one of the contact portions 1042 is still configured as the clamping terminal 1042c. Preferably, the grounding terminal is configured as the clamping terminal 1042c. In this way, the chip 104 may be effectively grounded, which is beneficial to prevent the chip 104 from being damaged due to sudden excessive current outputted by the imaging device.

Further, the chip assembly 104 in this embodiment also includes the conductor 107. As shown in the figure, the conductor 107 includes a front conductive member 1074 and a back conductive member 1075. The front conductive member 1074 is configured to be electrically connected to the corresponding stylus 91 to form the front contact portion on the front conductive member. The back conductive member 1075 is configured to be electrically connected to the back contact portion 1043.

The front conductive member 1074 and the back conductive member 1075 may be two components formed separately or may be a component formed integrally as shown in FIG. 12A. In this case, the conductor 107 also has a conductor base 1073. Both the front conductive member 1074 and the back conductive member 1075 are arranged on the conductor base 1073.

In the thickness direction of the substrate 1041, the conductor 107 is located between the substrate 1041 and the housing 101/inclined side wall 101e, and the substrate 1041 is not supported by the conductor 107, which is beneficial to improve the design freedom of the conductor 107. More specifically, the chip 104 also includes an exposure hole 1041c provided on the substrate 1041. The exposure hole 1041c penetrates the substrate 1041 in the thickness direction of the substrate 1041 to allow exposure of the front conductive member 1074. The front conductive member 1074 does not extend beyond the surface of the substrate provided with the front contact portion 1042.

As shown in FIG. 12B, the stylus corresponding to the clamping terminal 1042c is clamped by the clamping terminal 1042c. In this case, the side surface 91b of the stylus is in electrical contact with the clamping terminal 1042c, and the stylus corresponding to the front conductive member 1074 enters the exposure hole 1041c and is in electrical contact with the front conductive member 1074. Specifically, at least one of the contact end 91a, the side surface 91b, and the distal surface 91c of the stylus 91 entering the exposure hole 1041c is in electrical contact with the front conductive member 1074.

In this embodiment, not only the clamping terminal 1042c clamps the corresponding stylus, but also the movement of the stylus entering the exposure hole 1041c is limited by the side wall of the substrate forming the exposure hole 1041c, whereby the stylus is equivalently clamped by the exposure hole 1041c, which is beneficial to reduce the risk of the chip 104 being short-circuited, and to reduce the shaking amplitude of the stylus when the imaging device shakes greatly. Finally, the chip 104 and the stylus 91 form a stable electrical connection.

### Embodiment 9

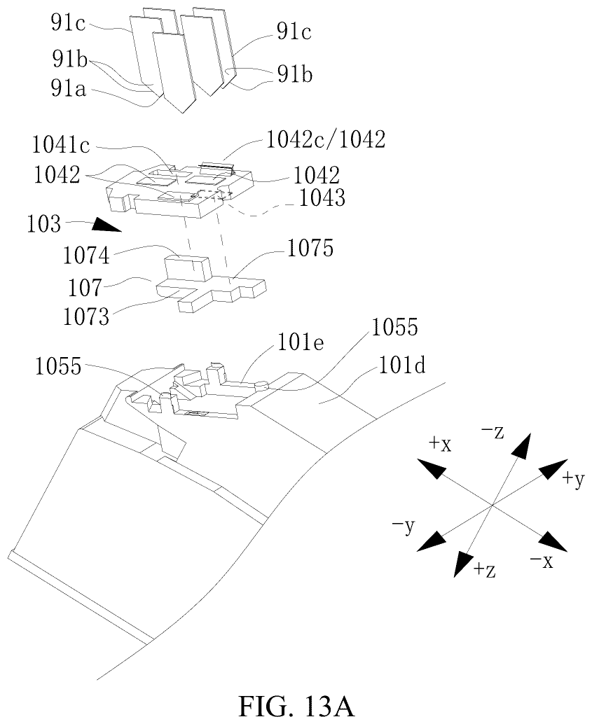

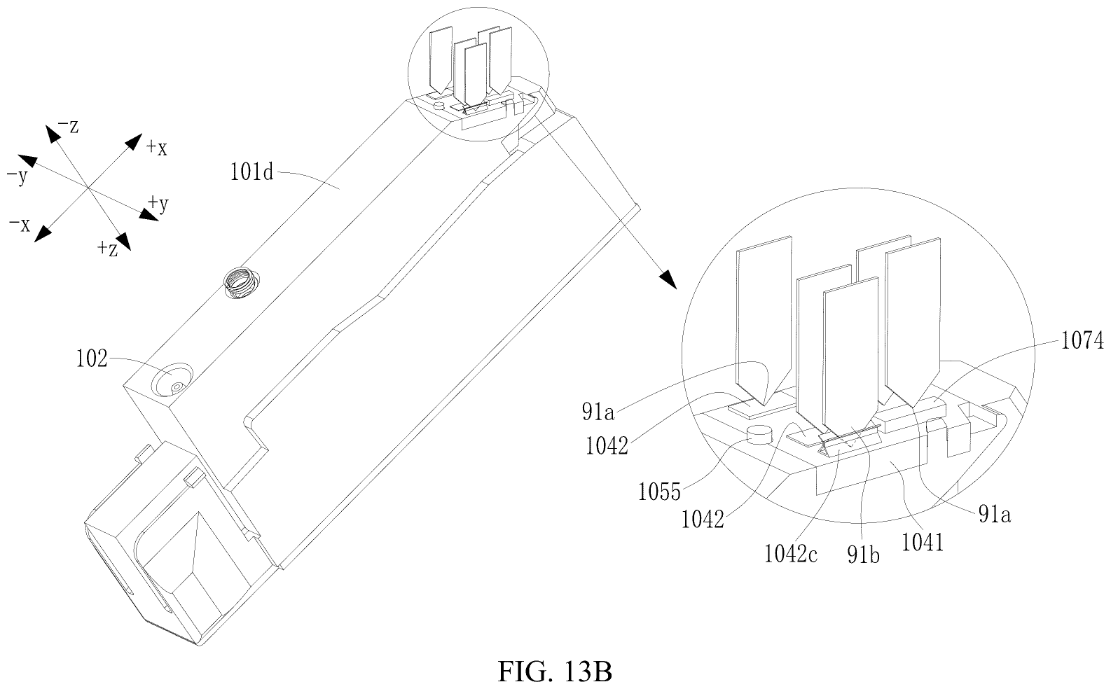

FIG. 13A is an exploded view of a chip assembly according to Embodiment 9 of the present invention after being separated from a housing. FIG. 13B is a perspective view of a chip assembly according to Embodiment 9 of the present invention when being in contact with a stylus assembly.

In Embodiment 8, the front conductive member 1074 is configured so as not to extend beyond the surface of the substrate provided with the front contact portion 1042. That is, the front conductive member 1074 does not extend beyond the exposure hole 1041c. Different from Embodiment 8, the front conductive member 1074 in this embodiment is configured so as to extend beyond the exposure hole 1041c. That is, the front conductive member 1074 extends beyond the surface of the substrate provided with the front contact portion 1042. As shown in FIG. 13A and FIG. 13B, compared with other contact portions 1042, the front conductive member 1074 protrudes from the substrate 1041, and the stylus corresponding to the front conductive member 1074 is in contact with the front conductive member 1074 through the contact end 91a thereof. In this way, the stylus will be subjected to a greater extrusion force. Similarly, the chip assembly 103 of this embodiment is beneficial to reduce the risk of the chip 104 being short-circuited, and can also reduce the shaking amplitude of the stylus when the imaging device shakes greatly. Finally, the chip 104 and the stylus 91 form a stable electrical connection.

### Embodiment 10

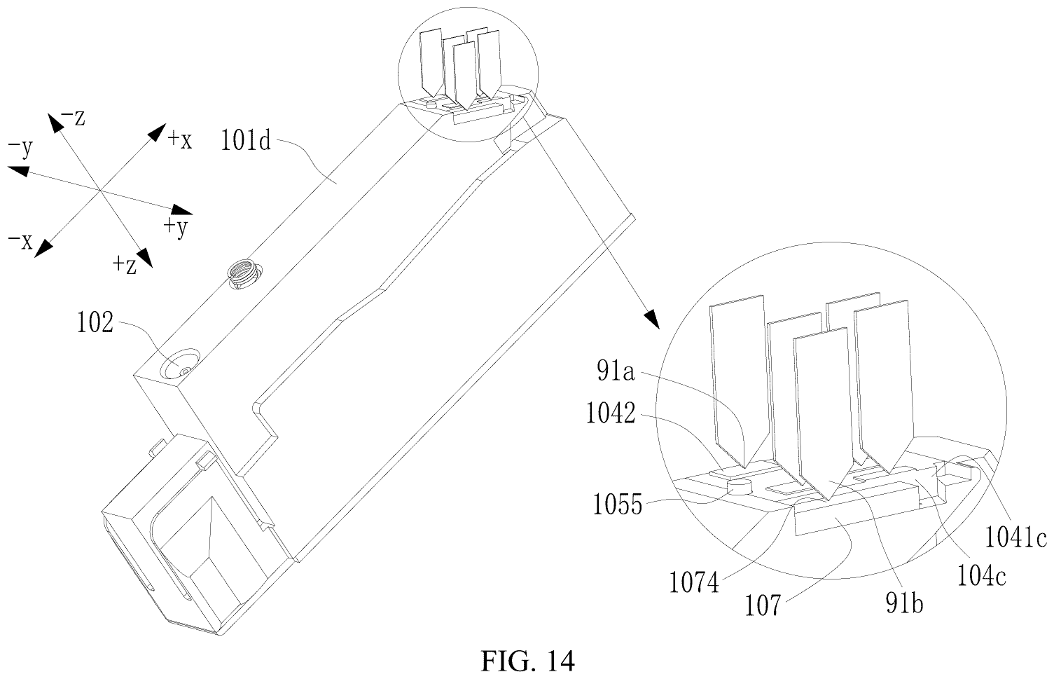

FIG. 14 is a perspective view of a chip assembly according to Embodiment 10 of the present invention when being in contact with a stylus assembly.

When the chip assembly 103 is in contact with the stylus assembly 90 in this embodiment, at least one stylus 91 is electrically connected to the front conductive member 1074, and it is not necessary to define whether the clamping terminal 1042c is required to be provided.

As shown in FIG. 14, similar to Embodiment 8, the front conductive member 1074 in this embodiment is also configured so as not to extend beyond the surface of the substrate provided with the front contact portion 1042. In this way, a height difference is formed between the substrate 1041 and the front conductive member 1074, and the front conductive member 1074 is lower than the substrate 1041. Specifically, a surface (third side) 104c extending in the thickness direction thereof in the substrate 1041 or a surface 104c between the surface provided with the front contact portion 1042 and the surface provided with the back contact portion 1043 in the substrate 1041 is adjacent to the front conductive member 1074. Equivalently, the exposure hole 1041c is provided at the edge of the substrate 1041, whereby at least one side of the exposure hole 1041c has no substrate.

According to Embodiment 2, the back contact portion 1043 may also be arranged on the third side 104c.

When the front conductive member 1074 is in contact with the corresponding stylus 91, the side surface 91b or the distal surface 91c of the stylus 91 will be opposite to the surface 104c. Similarly, the chip assembly 103 of this embodiment is beneficial to reduce the risk of the chip 104 being short-circuited, and can also reduce the shaking amplitude of the stylus when the imaging device shakes greatly. Finally, the chip 104 and the stylus 91 form a stable electrical connection.

Preferably, the front conductive member 1074 is configured to be in contact with the outermost stylus in the y direction. In this way, the size of the chip substrate 1041 can be reduced.

### Embodiment 11

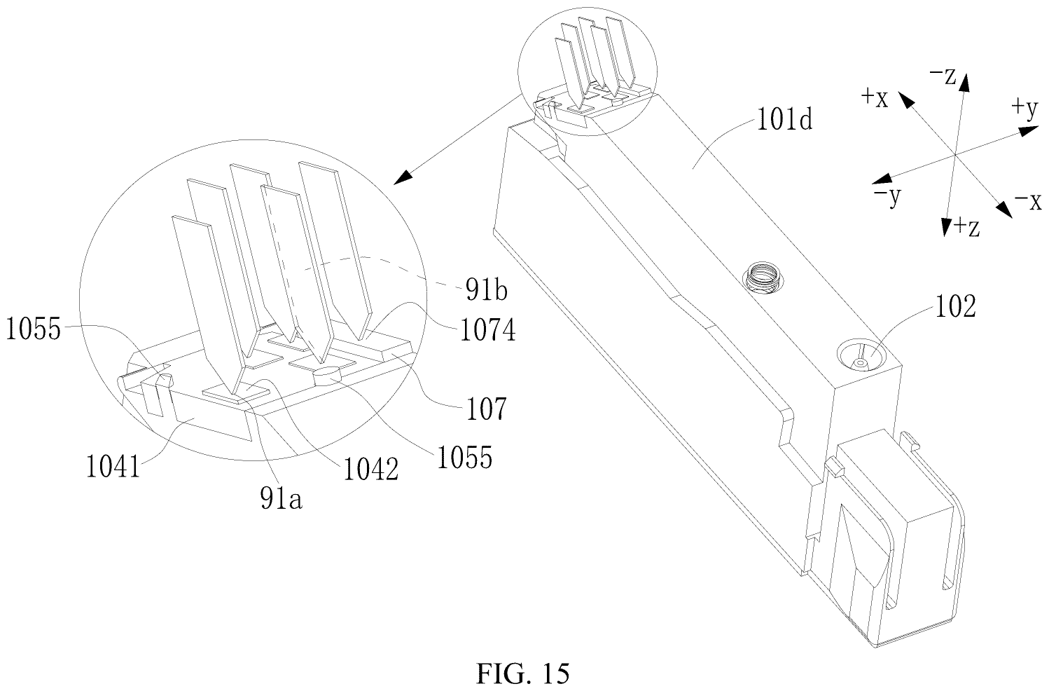

FIG. 15 is a perspective view of a chip assembly according to Embodiment 11 of the present invention when being in contact with a stylus assembly.

Similar to Embodiment 9, the front conductive member 1074 in this embodiment is configured so as to extend beyond the surface of the substrate provided with the front contact portion 1042. Other structures of the chip assembly 103 in this embodiment may be referred to Embodiment 10.

As shown in FIG. 15, when the front conductive member 1074 is in contact with the corresponding stylus 91, another stylus adjacent to the stylus 91 will be opposite to the front conductive member 1074. Similarly, the chip assembly 103 of this embodiment is beneficial to reduce the risk of the chip 104 being short-circuited, and can also reduce the shaking amplitude of the stylus when the imaging device shakes greatly. Finally, the chip 104 and the stylus 91 form a stable electrical connection.

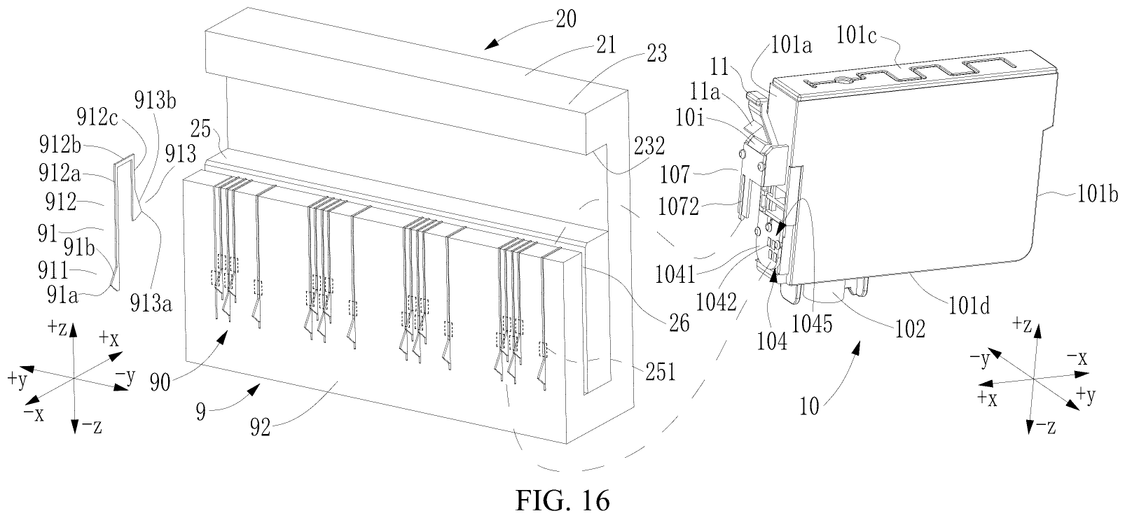

Other embodiments for preventing the chip from being short-circuited proposed by the applicant will be described below in conjunction with FIG. 16 to FIG. 20.

### Embodiment 12

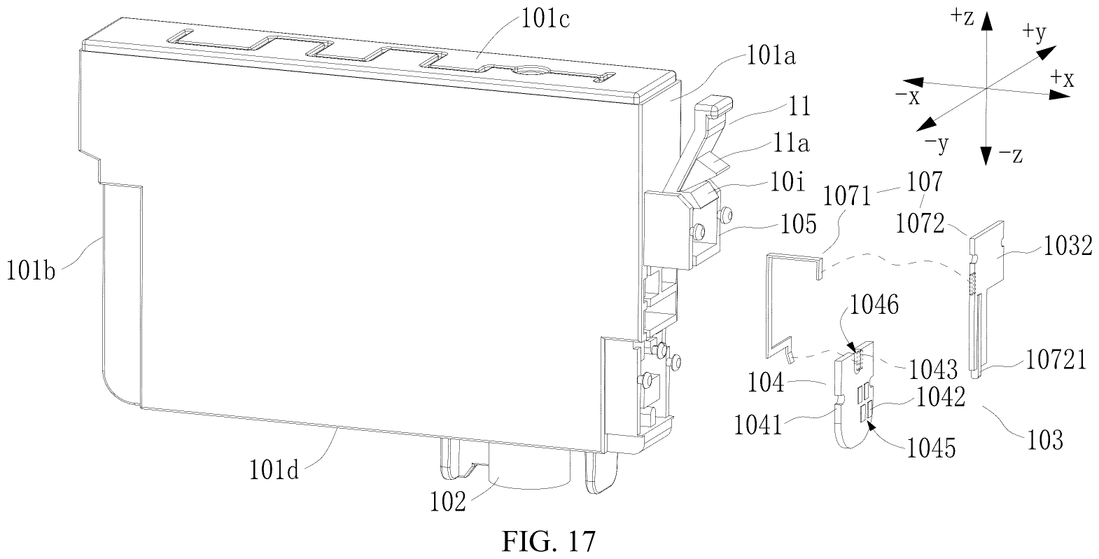

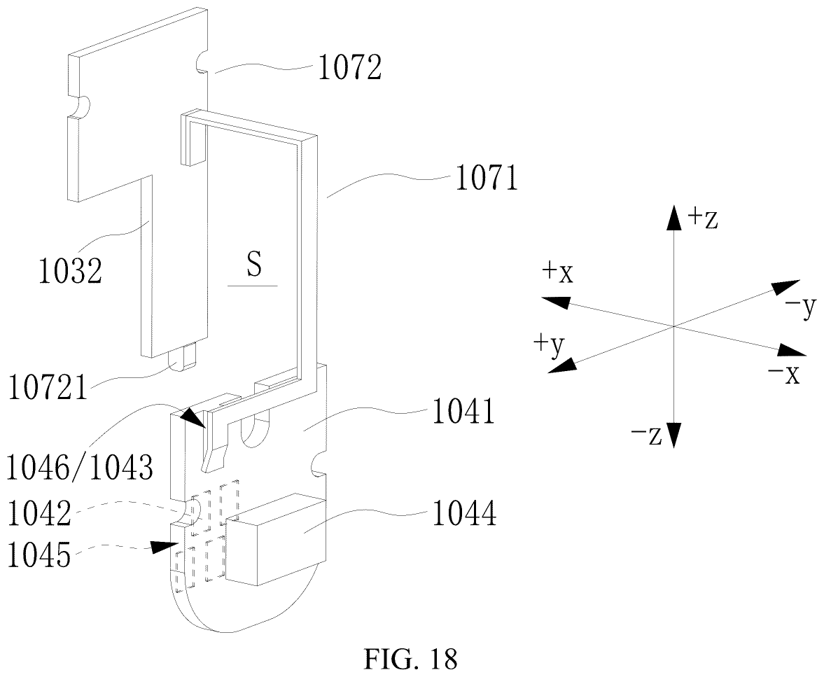

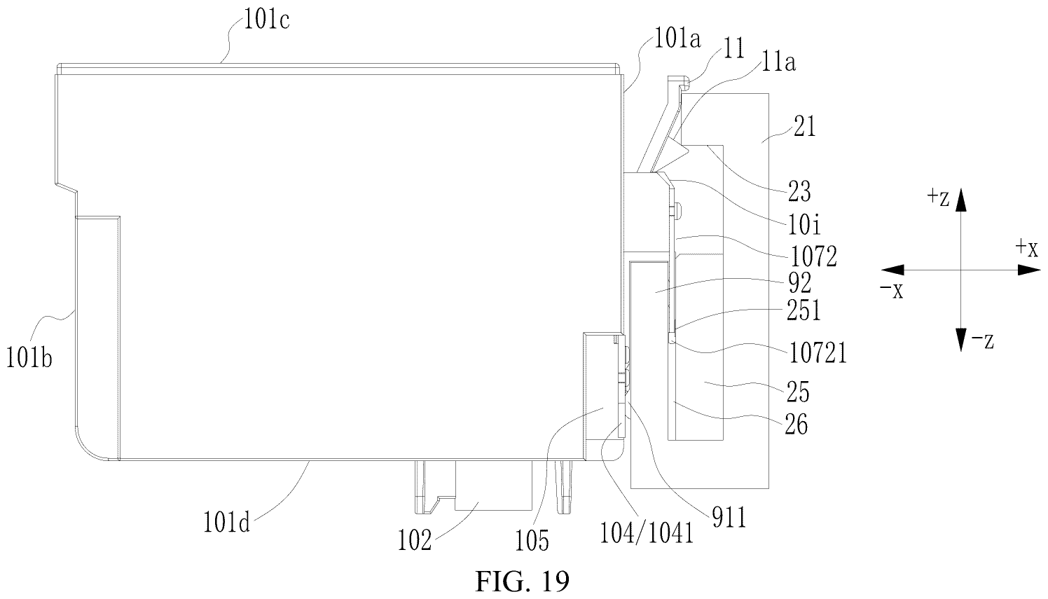

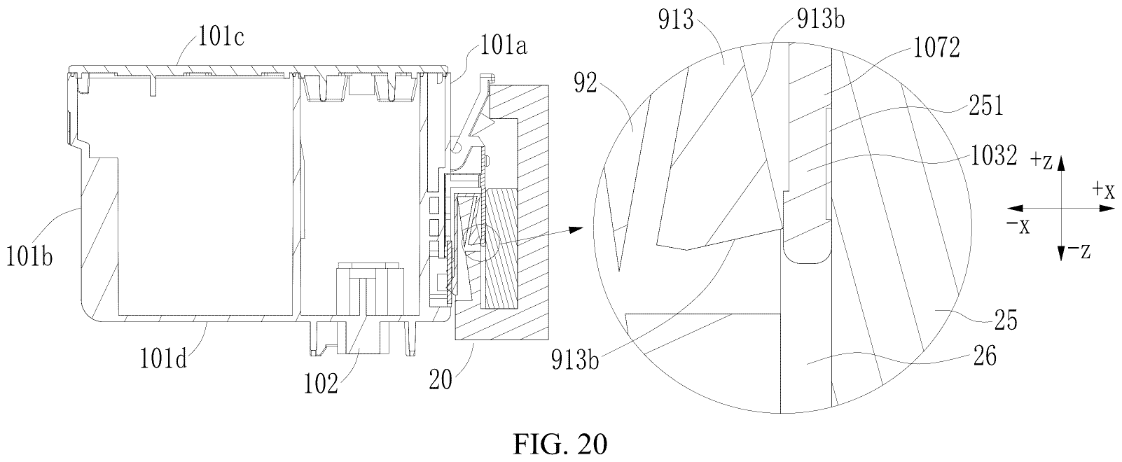

FIG. 16 is a state diagram of an imaging material box according to the present invention separated from an imaging material box containing portion in an imaging device to which the imaging material box is applied. FIG. 17 is a state diagram of a chip assembly according to Embodiment 12 of the present invention after being separated from a housing of an imaging material box. FIG. 18 is a perspective view of some components in a chip assembly according to Embodiment 12 of the present invention. FIG. 19 is a side view of an imaging material box provided with a chip assembly according to Embodiment 12 of the present invention when viewed in a y direction after being installed to an imaging device. FIG. 20 is a cross-sectional view of the imaging material box and the imaging device of FIG. 19 sectioned in a plane perpendicular to a y direction and passing through a contact position between a contact portion and a corresponding stylus.

Hereinafter, the imaging material box is still described as an ink box. Before the ink box 10 in this embodiment is described, an ink box containing portion 20 in the imaging device to which the ink box 10 is applied is described first.

As in the above embodiments, the ink box 10 is defined to have the x direction, the y direction, and the z direction shown in FIG. 16 based on the posture when the ink box 10 is installed to the imaging device, and the ink box containing portion 20 is set to have the same orientation as the ink box 10 for convenience of understanding. The left side of FIG. 16 shows the orientation of the ink box containing portion 20, and the right side shows the orientation of the ink box 10.

The ink box containing portion 20 includes a frame, a stylus mechanism 9 arranged on the frame, and a device-side circuit board 25. A slot 26 open in the +z direction is formed between the stylus mechanism 9 and the device-side circuit board 25. A plurality of device-side terminals 251 are arranged on the surface of the circuit board 25. One side plate 21 of the frame is provided with a device-side limiting element 23. The device-side limiting element 23 is provided with a device-side limiting portion 232 for limiting the ink box 10. As shown in the figure, the device-side limiting portion 232 is a step protruding from the side plate 21. The stylus mechanism 9 includes a main body 92 and stylus assemblies 90 arranged on the main body 92. Each ink box corresponds to one stylus assembly 90. Each stylus assembly 90 has a plurality of styli 91 arranged at intervals in the y direction. The number of styli 91 is the same as the number of chip contact portions 1042 and device-side terminals 251, and the structure of each stylus 91 is the same. In order to show the structure of the stylus 91 more clearly, FIG. 16 shows a perspective view of one of the styli separated from the main body 92.

The stylus 91 includes an outer contact member 911, an inner contact member 913, and a connecting member 912 for connecting the outer contact member and the inner contact member. The whole stylus 91 is made of a conductive material. The outer contact member 911 is configured to be electrically connected to the chip assembly 103. The inner contact member 912 is configured to be electrically connected to the device-side terminal 251. The shape of the connecting member 912 is matched with the shape of the main body 92. Typically, the connecting member 912 is arranged in an “n” shape as shown in the figure, including a first connection portion 912a extending in the z direction, a second connection portion 912b extending in the x direction, and a third connection portion 912c extending in the z direction. The first connection portion 912a and the third connection portion 912c are arranged at intervals in the x direction, the first connection portion 912a is also connected to the outer contact member 911, and the third connection portion 912c is also connected to the inner contact portion 913. When the stylus 91 is combined with the main body 92, the outer contact member 911 and the first connecting portion 912a face in the −x direction and may face against the ink box 10, and the inner contact member 913 and the third connecting portion 912c are located in the slot 26, face in the +x direction, and face against the circuit board 25. Before the ink box 10 is installed to the ink box containing portion 20, at least a part of the outer contact member 911 extends out of the main body 92, and the inner contact member 913 abuts against the device-side terminal 251. In this case, the inner contact member 913 and the third connecting portion 912c are retracted together into the main body 92 with the joint of the second connecting portion 912b and the third connecting portion 912c as a rotation point. When the ink box 10 is installed to a predetermined position of the ink box containing portion 20, the outer contact member 911 and the first connection portion 912a are retracted together into the main body 92 with the joint of the first connection portion 912a and the first connection portion 912a as a rotation point. The outer contact member 911 abuts against the chip assembly 103. Preferably, the outer contact member 911 and the inner contact member 912 are staggered in the z direction. In this way, when the outer contact member 911 is also retracted into the main body 92, the outer contact member 911 and the inner contact member 913 do not interfere, the internal space of the main body 92 can be fully utilized, and the overall size of the main body 92 can be reduced.

The outer contact member 911/inner contact member 913 is provided with a tapered tip 91a/913a and a side surface 91b/913b adjacent to the tapered tip. The side surface 91b is connected to the tapered tip 91a and the first connecting portion 912a, and the side surface 913b is connected to the tapered tip 913a and the third connecting portion 913a.

The ink box 10 in this embodiment is installed and disassembled/removed in the z direction. The ink box 10 also includes a first coupling member 11 in the front/+x direction of the front side wall 101a. When the ink box 10 is installed to the ink box containing portion 20, a coupling surface 11a at the first coupling member 11 abuts against the device-side limiting portion 232. Therefore, the movement of the ink box 10 in the z direction is limited and positioning is realized.

As shown in FIG. 17, similar to Embodiment 2, the chip assembly 103 in this embodiment includes a chip 104 and a conductor 107. The conductor 107 is configured to lead out at least one contact portion 1042 and be in contact with at least one of the stylus mechanism 9 and the device-side terminal 251. That is, at least one of the plurality of contact portions arranged in the chip 104 is not in direct contact with the stylus mechanism 9. In this way, the positions of the plurality of contact portions on the substrate 1041 may not be limited to the same surface, thereby reducing the risk of the chip 104 being short-circuited. When the number of contact portions 1042 is five as described above, at least one of the power terminal 10424 and the grounding terminal 10425 may be led out by the conductor 107 and is in contact with at least one of the stylus mechanism 9 and the device-side terminal 251. Preferably, the grounding terminal 10425 is led out by the conductor 107 and is in contact with at least one of the stylus mechanism 9 and the device-side terminal 251.

Similar to Embodiment 2, in this embodiment, the plurality of contact portions 1042 are divided into a first group of contact portions 1045 arranged on one side of the substrate 1041 and a second group of contact portions 1046 arranged on the other side of the substrate 1041. Hereinafter, for example, the second group of contact portions 1046 is provided with only one back contact portion 1043. The position of the back contact portion 1043 on the other side of the substrate 1041 should not be limited. For example, when viewed in the x direction, the back contact portion 1043 may be located in the first region Q1 or the second region Q2. Since the first group of contact portions 1045 and the second group of contact portions 1046 are respectively located on both sides of the substrate 1041, the risk of the chip 104 being short-circuited can be reduced regardless of a position where the back contact portion 1043 is arranged on the other side of the substrate.

The conductor 107 is configured to lead out the back contact portion 1043 and be in contact with the corresponding stylus 91. As shown in the figure, the conductor 107 includes a first conductive member (back conductive member 1075) 1071 and a second conductive member (front conductive member 1074) 1072 electrically connected to each other, which may be formed integrally or separately. The second conductive member 1072 is located in front of the substrate 1041. In the x direction, the second conductive member 1072 and the substrate 1041 are spaced apart from each other to form a coupling space S therebetween. One end of the first conductive member 1071 is in contact with the back contact portion 1043 and the other end is in contact with the second conductive member 1072. In this way, the back contact portion 1043 is equivalent to being arranged on the second conductive member 1072. Preferably, the back contact portion 1043 is a grounding terminal and is arranged in the first region Q1. Further, the chip assembly 103 also includes a supporting member (conductor base 1073) 1032 for supporting the second conductive member 1072. A tail end 10721 of the second conductive member 1072 protrudes from the supporting member 1032.

In some implementations, the back contact portion 1043 may alternatively be arranged on the same side of the substrate as the front contact 1042 as long as the conductor 107 can lead out the back contact portion 1043 and is in contact with at least one of the stylus mechanism 9 and the device-side terminal 251.

In some implementations, a part of the second conductive member 1072 may alternatively be arranged in the rear, front, bottom, left, or right of the substrate 1041 as long as the second conductive member 1072 can be in contact with at least one of the inner contact member 913 and the device-side terminal 251.

When the ink box 10 is installed, the main body 92 of the stylus mechanism 9 enters the coupling space S, the outer contact member 911 abuts against the first group of contact portions 1045 among the contact portions. The supporting member 1032 enters the slot 26 with the second conductive member 1072. The second conductive member 1072 is in contact with at least one of the inner contact member 913 and the device-side terminal 251. As shown in FIG. 20, the supporting member 1032 is inserted between the inner contact member 913 and the device-side terminal 251. In this case, the supporting member 1032/second conductive member 1072 abuts against the tapered tip 913a of the inner contact member 913, and the inner contact member 913 and the third connecting portion 912c are retracted together into the main body 92. In addition, the second conductive member 1072 is in contact with the device-side terminal 251. Finally, a plurality of contact portions 1042 of the chip 104 are electrically connected directly or indirectly to the device-side terminal 251. The first group of contact portions 1045 is electrically connected to the device-side terminal 251 through the stylus 91, and the second group of contact portions 1046 is electrically connected to the device-side terminal 251 through the conductor 107.

Further, when the ink box 10 reaches a predetermined installation position, both the outer contact member 911 and the inner contact member 912 are retracted into the main body 91. In the x direction, the outer contact member 911 will apply a force toward the −x direction to the ink box 10, and the inner contact member 911 will apply a force toward the +x direction to the ink box 10. The two opposite forces will enable the ink box 10 to be more stably positioned in the ink box containing portion 20. In addition, the plurality of contact portions of the chip 104 are no longer arranged on the same surface of the substrate 1041, and the risk of the chip 104 being short-circuited can be effectively reduced.

As a modification of this embodiment, the whole supporting member 1032 may be made of a conductive material. In this case, the whole supporting member 1032 is made of the second conductive member 1072. Similarly, when the ink box 10 is installed, the second conductive member 1072 is electrically connected to the device-side terminal 251.

As another modification of this embodiment, the second conductive member 1072 may alternatively be contacted by a member other than the outer contact member 911 of the stylus 91, thereby realizing the electrical connection between the second conductive member 1072 and the device-side terminal 251. For example, when the ink box 10 is installed to a predetermined position, the second conductive member 1072 does not enter between the inner contact member 913 and the device-side terminal 251, but reaches the top/+z direction of the tapered tip 913a. In this case, the second conductive member 1072 may be contacted with at least any one of the side surface 913b, the third connection portion 912c, and the second connection portion 912b of the inner contact member. Since the tapered tip 913a of the inner contact member still maintains contact with the device-side terminal 251, the second conductive member 1072 can be electrically connected to the device-side terminal 251.

Furthermore, when all the contact portions 1042 of the chip 104 are led out through the conductor 107 without being in contact with the outer contact member 911, that is, all the contact portions 1042 of the chip 104 enter the slot 26 through the conductor 107 and are in contact with at least one of the inner contact member 911, the second connection portion 912b, the third connection portion 912c, and the device-side terminal 251, since the ink discharge portion 102 is still located on the side of the main body 92 facing the ink box, the contact position of each second conductive member 1072 with at least one of the inner contact member 911, the second connection portion 912b, the third connection portion 912c, and the device-side terminal 251 is separated from the ink discharge portion 102 by the main body 92 in the x direction, which is also beneficial to reduce the risk of the chip 104 being short-circuited. According to this modification, it is not necessary to define whether the plurality of contact portions 1042 are arranged on the same surface. That is, all the contact portions 1042 may be arranged on the same surface, at least one contact portion is led out through the conductor 107, and the conductor 107 is not in contact with the outer contact member 911, but is in contact with a member other than the outer contact member 911.

### Embodiment 13

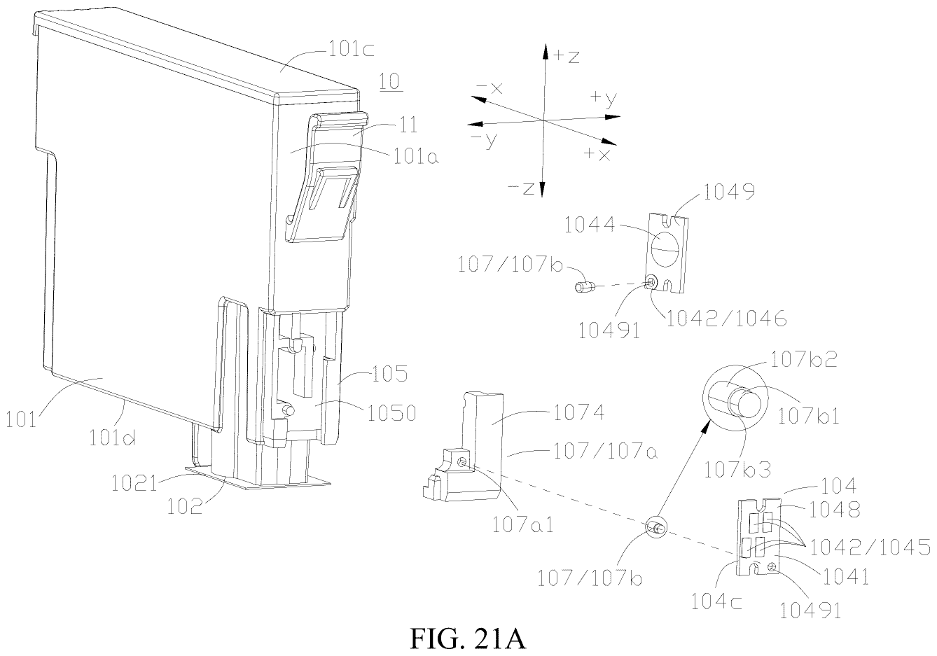

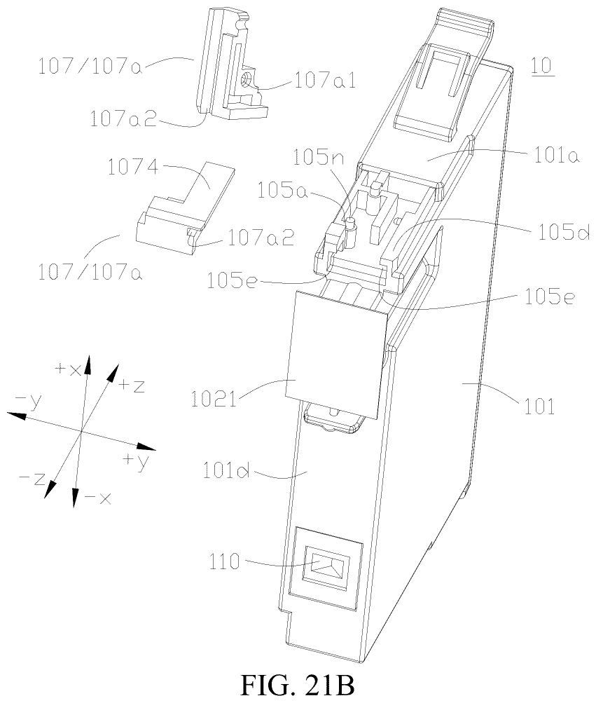

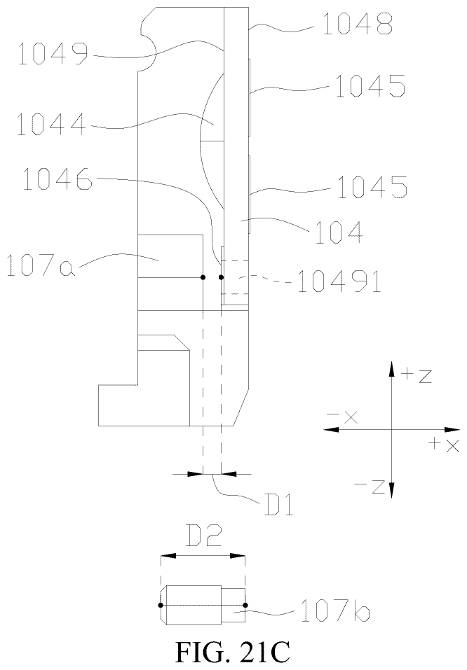

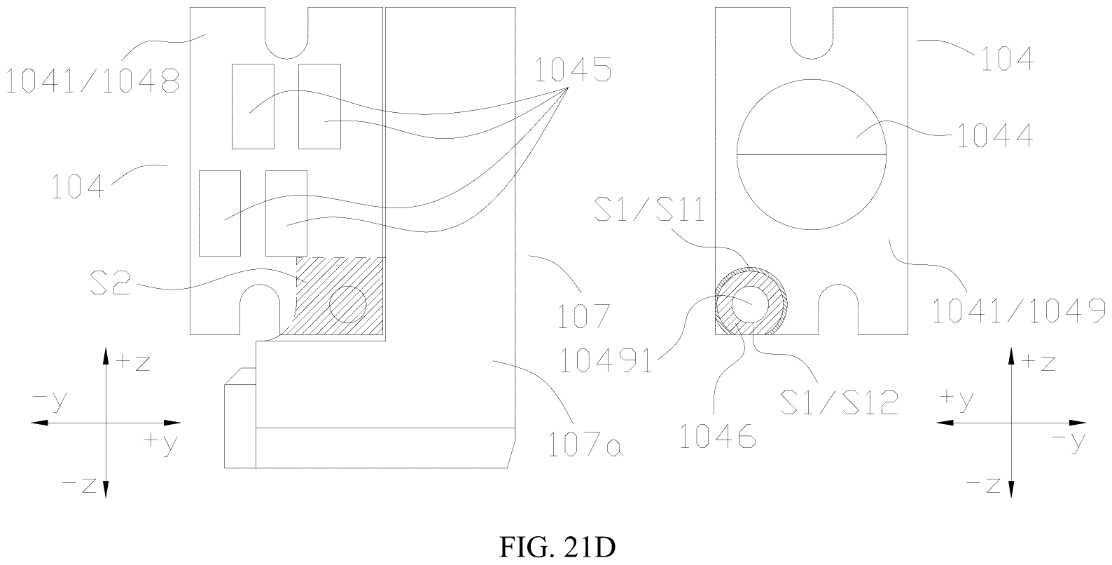

As shown in FIG. 21A and FIG. 21B, a conductor 107 according to this embodiment includes a first conductive member 107a and a second conductive member 107b. The first conductive member 107a is at least configured to be in electrical contact with a stylus, and the second conductive member 107b is at least configured to be in electrical contact with a chip 104/a back contact portion 1046/a second group of contact portions 1046. Further, the second conductive member 107b is configured to form an electrical contact between the chip 104 and the first conductive member 107a. Further, the first conductive member 107a and the second conductive member 107b may be formed integrally or formed separately. In this embodiment, it is preferred that the first conductive member 107a and the second conductive member 107b are formed separately. In other words, the first conductive member 107a and the second conductive member 107b are separated from each other.

The conductor 107 may be made of a conventional conductive material such as metal, conductive silica gel, conductive plastic, conductive ceramic, or carbon oil, etc. In other words, the first conductive member 107a and the second conductive member 107b may be made of the same or different conductive materials.

The chip 104 and the first conductive member 107a are arranged at intervals along an extending direction of the second conductive member 107b. Specifically, the extending direction of the second conductive member 107b refers to a direction in which the second conductive member 107b extends toward the back contact portion/second group of contact portions 1046. For example, in this embodiment, the second conductive member 107b extends toward the back contact portion/second group of contact portions 1046 along an x direction. In the x direction, the second conductive member 107b is located in a +x direction of the first conductive member 107a, and the second conductive member 107b is located in a −x direction of the chip 104. In other words, the second conductive member 107b is arranged between the chip 104 and the first conductive member 107a. Further, one end of the second conductive member 107b is in electrical contact with the chip 104, and the other end is in electrical contact with the first conductive member 107a. Furthermore, along the x direction/a thickness direction of the chip 104 (arrangement direction of a first side 1048 and a second side 1049), the chip 104 is provided with a first installation hole 10491, the first conductive member 107a is provided with a second installation hole 107a1, and one end of the second conductive member 107b is combined with the first installation hole 10491. Specifically, the second conductive member 107b has a first portion 107b1, a second portion 107b2, and a third portion 107b3 located between the first portion 107b1 and the second portion 107b2. The first portion 107b1 is configured to be combined with the first installation hole 10491, and the second portion 107b2 is configured to be combined with the first installation hole 107a1. When the first conductive member 107a and the second conductive member 107b are formed integrally, the first installation hole 107a1 may be canceled. Along the x direction/the thickness direction of the chip 104 (arrangement direction of the first side 1048 and the second side 1049), the third portion 107b3 is a step surface formed between the first portion 107b1 and the second portion 107b2. The back contact portion/second group of contact portions 1046 is arranged on the second side 1049 of the chip 104. Preferably, the back contact portion/second group of contact portions 1046 is configured to extend around an edge of the first installation hole 10491. The back contact portion/second group of contact portions 1046 may extend around the edge of the first installation hole 10491 to form a complete ring shape, for example, an annular shape, or may extend around the partial edge the first installation hole 10491 to form a belted structure, for example, a circular arc shape. While the first portion 107b1 of the second conductive member 107b is combined with the first installation hole 10491, the third portion 107b3 is in electrical contact with the back contact portion/second group of contact portions 1046, the second portion 107b2 of the second conductive member 107b is combined with the second installation hole 107a1, so that the stability of an electrical connection between the conductor 107 and the chip 104 is better, thereby forming an electrical connection path: chip 104—second conductive member 107b—first conductive member 107a—stylus. In some implementations, the back contact portion/second group of contact portions 1046 may also be arranged: partially on the second side 1049 of the chip and partially on an inner wall of the first installation hole 10491. In some implementations, the back contact portion/second group of contact portions 1046 may also be entirely arranged on the inner wall of the first installation hole 10491. Further, when the back contact portion/second group of contact portions 1046 is arranged on the inner wall of the first installation hole 10491, the second conductive member 107b may also be electrically connected to the back contact portion/second group of contact portions 1046 by welding/interference fit. In the x direction/the thickness direction of the chip 104 (arrangement direction of the first side 1048 and the second side 1049), the second conductive member 107b is arranged between the first conductive member 107a and the chip 104. To be specific, the chip 104 and the first conductive member 107a are arranged at intervals. In other words, the first conductive member 107a does not support the chip 104, so that the friction between the first conductive member 107a and the chip 104 can be avoided, thereby preventing the chip 104 from being damaged by the first conductive member 107a. At the same time, the contact area between the second conductive member 107b and the chip 104 is small, and the friction between the second conductive member 107b and the chip 104 is small, thereby reducing the wear of the chip 104, avoiding the damage of the chip 104, and improving the reuse rate of the chip when an ink box is recycled.

In some implementations, the second conductive member 107b is arranged between the first conductive member 107a and the chip 104 along a y direction. To be specific, the first conductive member 107a and the chip 104 are arranged at intervals.

Further, as shown in FIG. 21C, in the x direction/the thickness direction of the chip 104 (arrangement direction of the first side 1048 and the second side 1049), an interval between the first conductive member 107a and the chip 104 is D1. Along the +x direction (direction of the first conductive member 107a facing the back contact portion/second group of contact portions 1046), the size of the second conductive member 107b is D2. Preferably, D2 is greater than or equal to D1.

Further, as shown in FIG. 21D, a contact area between the second conductive member 107b and the chip 104 is S1, and an area where the first conductive member 107a overlaps with a substrate 1041/the chip 104 is S2 along the x direction/the thickness direction of the chip 104 (arrangement direction of the first side 1048 and the second side 1049). Preferably, S1 is less than or equal to S2. Further, the contact area S1 between the second conductive member 107b and the chip 104 includes a projected area S11 and a projected area S12 along the x direction. A projected area in the x direction of a region where the second conductive member 107b is in contact with the back contact portion/second group of contact portions 1046 is S12. A total projected area of the second conductive member 107b on the second side 1049 along the x direction minus the projected area S12 is the projected area S11. Specifically, the projected area S11 is a region where the second conductive member 107b is in contact with the chip 104 and is not in contact with the back contact portion/second group of contact portions 1046. In some embodiments, the projected area S11 may be 0. In this case, the position of the projected area S12 completely coincides with the back contact portion/second group of contact portions 1046, and the projected area S12 is less than or equal to the area of the back contact portion/second group of contact portions 1046. In addition, when the second conductive member 107b is electrically connected to the back contact portion/second group of contact portions 1046 by soldering, a portion formed by the soldering may be regarded as a part of the second conductive member 107b.

Since the size D2 of the second conductive member 107b is greater than or equal to the interval D1 between the first conductive member 107a and the chip 104, the contact area S1 between the second conductive member 107b and the chip 104 is less than or equal to the area S2 where the first conductive member 107a overlaps with the substrate 1041. Even if the chip 104 is pressed by an external force and elastically deforms/displaces, the first conductive member 107a is less likely to rub against a non-contact portion of the substrate 1041 (a region other than the contact area S2), and only the second conductive member 107b in the conductor 107 rubs against the back contact portion/second group of contact portions 1046. Therefore, the conductor 107 is less likely to damage the chip 104 (for example, insulating layer).

The chip 104 is installed toward a chip containing portion 1050 along the −x direction. Specifically, during installation, the second conductive member 107b may be fixed on the substrate 1041 of the chip 104, and then the first conductive member 107a may be fixed on an ink box 10. Preferably, the first conductive member 107a may be fixed on a positioning plate 105, and finally a combination of the chip 104/the substrate 1041 and the second conductive member 107b may be installed onto the ink box 10/the positioning plate 105, or finally the chip 104/the substrate 1041 may be installed on the ink box 10/the positioning plate 105. Alternatively, the second conductive member 107b is fixed on the first conductive member 107a first, and then subsequent installation steps are performed. Preferably, during the installation, the second conductive member 107b is first soldered to the substrate 1041/the chip 104, and then the combination of the substrate 1041/the chip 104 and the second conductive member 107b is installed onto the ink box 10. More preferably, the second conductive member 107b and the second installation hole 107a1 in the first conductive member 107a are fixed by pressing (interference fit).

In this embodiment, the first conductive member 107a overlaps with the chip 104 in the y direction and/or a z direction. Further, the first conductive member 107a is combined with the housing 101. Preferably, the first conductive member 107a is clamped to the positioning plate 105. In this embodiment, a second blocking portion 105d of the positioning plate 105 is arranged on a side close to a +y direction. The second blocking portion 105d is configured to cooperate with the first conductive member 107a. A clamping groove 105e of the positioning plate 105 extends along the z direction. The clamping groove 105e is configured to cooperate with the first conductive member 107a to guide the first conductive member 107a to be slidably installed to the positioning plate 105. Furthermore, the first conductive member 107a is provided with a groove portion 107a2 at one end in the +y direction. When the first conductive member 107a is slidably installed toward the positioning plate 105 along a +z direction, the groove portion 107a2 of the first conductive member 107a is configured to cooperate with the second blocking portion 105d, so that the combination of the first conductive member 107a and the positioning plate 105 is more stable. At the same time, the groove portion 107a2 is located in a −x direction of a front conductive member 1074 along the x direction, so that the front conductive member 1074 of the first conductive member 107a can have a sufficiently large surface area, and the stylus can be better in electrical contact with the front conductive member 1074.

Preferably, the back contact portion/second group of contact portions 1046 is a ground terminal.

In some implementations, the back contact portion/second group of contact portions 1046 may also be arranged on a third side 104c. Then, the back contact portion/second group of contact portions 1046 is in electrical contact with the first conductive member 107a. For example, the back contact portion/second group of contact portions 1046 faces the +y direction or a −z direction. In this case, the second conductive member 107b is configured to be non-conductive for only supporting the chip 104. In this way, the design freedom of the chip 104 and the conductor 107 can be improved.

In this embodiment, after the chip 104 is installed on the ink box 10/the positioning plate 105, the back contact portion/second group of contact portions 1046 is located on the second side 1049 of the substrate 1041. The second conductive member 107b is located in the −x direction of the second side 1049 of the substrate 1041. A part of the first conductive member 107a is located in the −x direction of the second side 1049 of the substrate 1041, and the other part of the first conductive member 107a is located in the +y direction and/or the −z direction of the third side 104c of the substrate 1041.

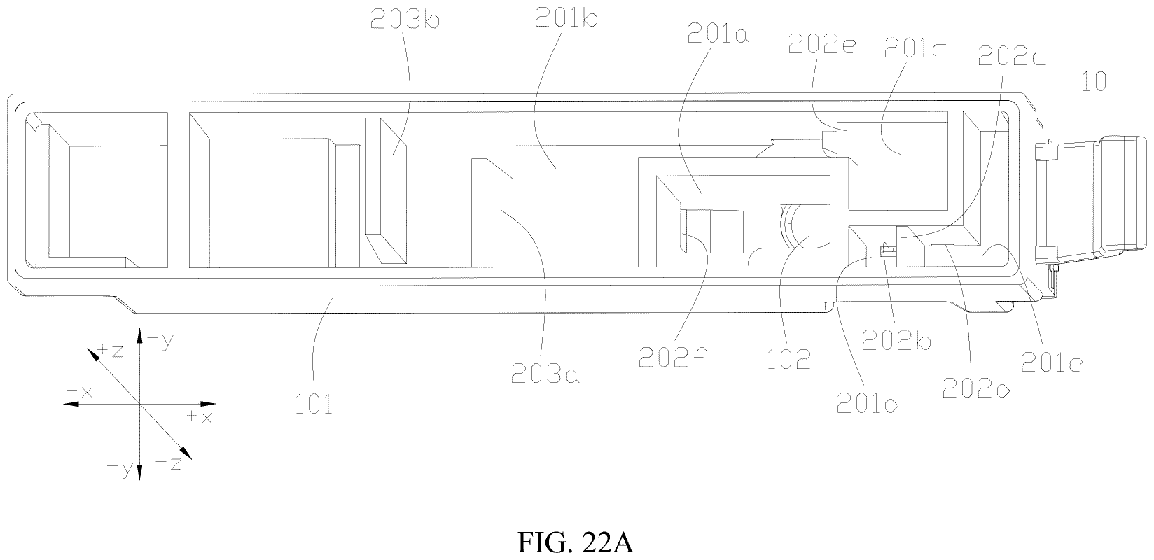

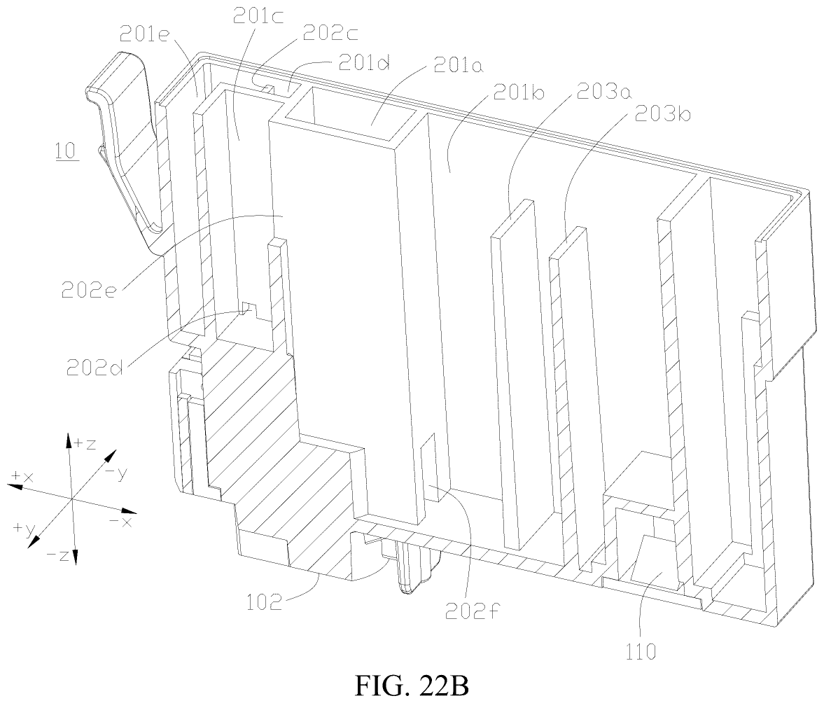

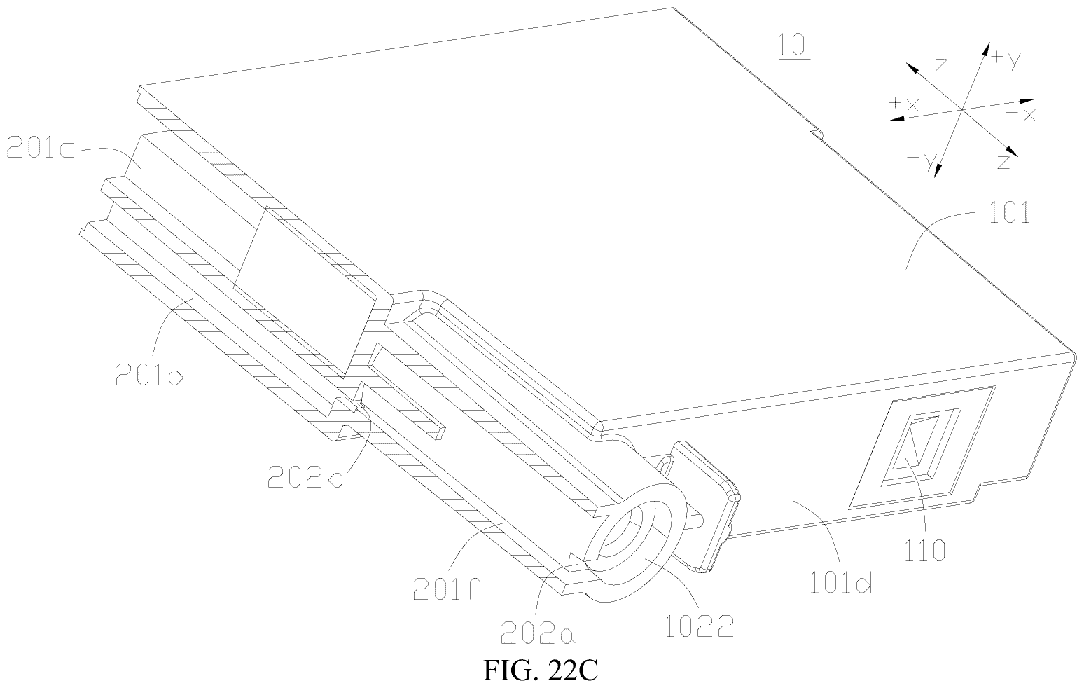

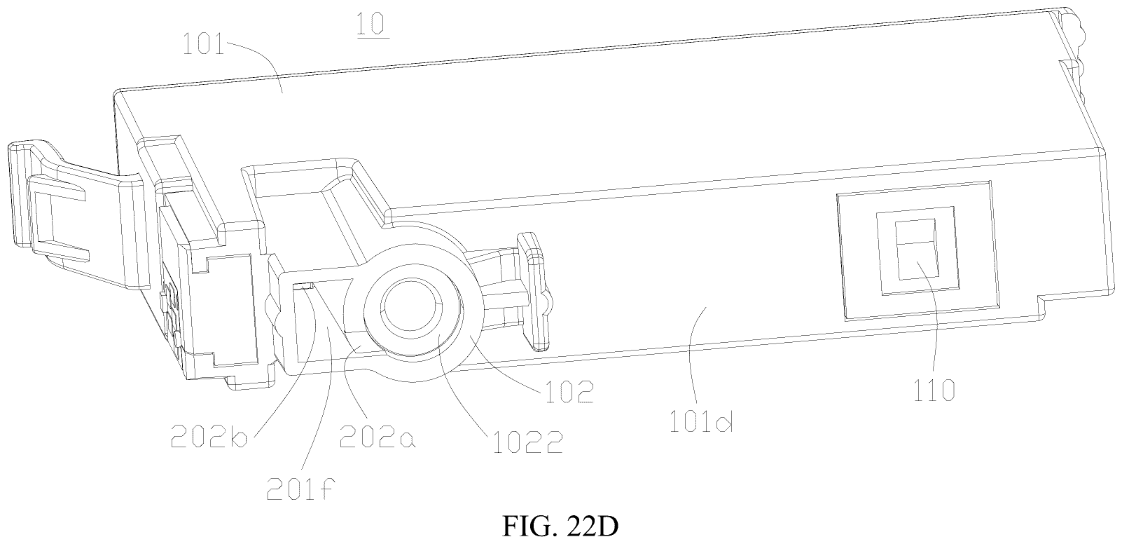

As shown in FIG. 22A to FIG. 22D, in this embodiment, the ink box 10 includes a first ink cavity 201a, a second ink cavity 201b, and a third ink cavity 201c for containing ink. The first ink cavity 201a and the second ink cavity 201b are communicated with each other, and the second ink cavity 201b and the third ink cavity 201c are communicated with each other. Further, the first ink cavity 201a is communicated with an ink discharge portion 102. The ink in the first ink cavity 201a is supplied to an imaging device through the ink discharge portion 102. A sponge is arranged in the third ink cavity 201c or a second air cavity 201e described hereinafter. The sponge is configured to absorb part of the ink and cover a third air guide port 202d described hereinafter to prevent the ink from flowing backwards. The ink box 10 further includes an air intake cavity 201f, a first air cavity 201d, and the second air cavity 201e. The air intake cavity 201f can be communicated with air, the first air cavity 201d and the second air cavity 201e can be communicated with each other, and the second air cavity 201e and the third ink cavity 201c can be communicated with each other.

Further, the air can be communicated with the air intake cavity 201f through an air intake port 202a. In the z direction, the air intake port 202a and an ink discharge port 1022 provided in the ink discharge portion 102 are both located on a side facing the −z direction, and the air intake port 202a is adjacent to the ink discharge port 1022. The air intake cavity 201f and the first air cavity 201d are communicated with each other through a first air guide port 202b. After the air enters the air intake cavity 201f from the air intake port 202a, the air enters the first air cavity 201d from the first air guide port 202b. The first air cavity 201d and the second air cavity 201e are communicated with each other through a second air guide port 202c. The second air cavity 201e and the third ink cavity 201c are communicated with each other through the third air guide port 202d. The third ink cavity 201c and the second ink cavity 201b are communicated with each other through a first communication port 202e. The second ink cavity 201b and the first ink cavity 201a are communicated with each other through a second communication port 202f.

Furthermore, before the ink box 10 is started to use, the air intake port 202a and the ink discharge port 1022 are simultaneously sealed by a sealing member 1021. Preferably, the sealing member 1021 is a sealing film. When the ink box 10 is installed in place, an ink absorbing member arranged in the imaging device punctures the sealing member 1021 and then is combined with the ink discharge portion 102. In this case, the air intake port 202a is communicated with the air, and the air enters the ink box 10 from the air intake port 202a to balance the air pressure inside and outside the ink box 10, so that the ink can flow out.

Furthermore, the sponge arranged in the third ink cavity 201c or the second air cavity 201e is configured to hold the ink to prevent the ink from flowing out of the third air guide port 202d, and even if the ink flows out of the third air guide port 202d, the ink is first contained by the second air cavity 201e without immediately flowing out of the ink box 10, thereby preventing the ink box 10 and the imaging device from being contaminated.

Furthermore, the ink box 10 further includes an ink level detection member 110. The ink level detection member 110 is configured to detect an ink level in the ink box 10. Preferably, the ink level detection member 110 is arranged on a lower side wall 101d of the ink box 10, and more preferably, the ink level detection member 110 is provided as a prism.

While the above embodiments respectively describe chip assemblies 103 and/or ink boxes having different or varied structures, it should be understood that any combination of the above embodiments may be made by those skilled in the art according to actual design requirements.

What is claimed is:

1. A chip assembly, configured to be installed in an imaging material box, the imaging material box being detachably installed on an imaging device provided with a stylus,
the chip assembly comprising a chip and a conductor, and the chip comprising a substrate and a plurality of contact portions arranged on the substrate,
wherein
the plurality of contact portions comprise a front contact portion arranged on a first side of the substrate and a back contact portion arranged on a second side of the substrate,
the front contact portion being configured to be in contact with the stylus, and the back contact portion being electrically connected to the stylus through the conductor.

2. The chip assembly according to claim 1, wherein the first side of the substrate is opposite to the second side.

3. The chip assembly according to claim 1, wherein the first side is opposite to the second side, and the back contact portion is arranged on a surface different from both the first side and the second side.

4. The chip assembly according to claim 1, wherein the back contact portion is arranged on a third side of the substrate, and the third side is a surface extending in a thickness direction of the substrate.

5. The chip assembly according to claim 1, wherein the imaging device is provided with a device-side terminal for electric connection with the stylus, the conductor comprises a first conductive member and a second conductive member electrically connected to each other, a first end of the first conductive member is in contact with the back contact portion and a second end of the first conductive member is in contact with the second conductive member, and the second conductive member is configured to be in contact with the device-side terminal or the stylus.

6. The chip assembly according to claim 1, wherein at least one contact portion is arranged higher than other contact portions.

7. The chip assembly according to claim 6, wherein the conductor is in contact with the stylus to form the front contact portion on the conductor, and a height difference is formed between at least one front contact portion and other front contact portions in the chip assembly.

8. The chip assembly according to claim 1, wherein the substrate comprises a first sub-substrate and a second sub-substrate formed separately, the contact portions comprise a first sub-contact portion arranged on the first sub-substrate and a second sub-contact portion arranged on the second sub-substrate, and the back contact portion is the first sub-contact portion or the second sub-contact portion.

9. The chip assembly according to claim 8, wherein the first sub-substrate and the second sub-substrate are movable relatively.

10. A chip assembly, configured to be installed in an imaging material box, the imaging material box being detachably installed on an imaging device provided with a stylus,
the chip assembly comprising a chip and a conductor, and the chip comprising a substrate and a plurality of contact portions arranged on the substrate,
wherein
the plurality of contact portions comprise:
a front contact portion, configured to be directly electrically connected to the stylus; and
a back contact portion, not arranged on an identical side as the front contact portion, a first end of the conductor being configured to be in contact with the back contact portion and a second end of the conductor being configured to be in contact with the stylus.

11. The chip assembly according to claim 10, wherein at least one contact portion is arranged higher than other contact portions.

12. The chip assembly according to claim 11, wherein the conductor is in contact with the stylus to form the front contact portion on the conductor, and a height difference is formed between the at least one contact portion and the other contact portions in the chip assembly.

13. The chip assembly according to claim 11, wherein the imaging device is provided with a device-side terminal for electric connection with the stylus, the conductor comprises a first conductive member and a second conductive member electrically connected to each other, a first end of the first conductive member is in contact with the back contact portion and a second end of the first conductive member is in contact with the second conductive member, and the second conductive member is configured to be in contact with the device-side terminal or the stylus.

14. The chip assembly according to claim 12, wherein the conductor comprises a front conductive member and a back conductive member electrically connected to each other, the front conductive member is configured to be electrically connected to the stylus, and the back conductive member is configured to be electrically connected to the back contact portion; and
the substrate is provided with an exposure hole for allowing exposure of the front conductive member, and the front conductive member does not extend beyond a surface provided with the front contact portion.

15. The chip assembly according to claim 12, wherein the conductor comprises a front conductive member and a back conductive member electrically connected to each other, the front conductive member is configured to be electrically connected to the stylus, and the back conductive member is configured to be electrically connected to the back contact portion; and
the substrate is provided with an exposure hole for allowing exposure of the front conductive member, and the front conductive member extends beyond a surface provided with the front contact portion.

16. The chip assembly according to claim 1, wherein at least one contact portion is in contact with a side surface of the stylus.

17. The chip assembly according to claim 1, wherein at least one contact portion clamps the stylus.

18. The chip assembly according to claim 1, wherein at least one contact portion is formed as a clamping terminal for clamping the stylus, and the clamping terminal is electrically connected to the conductor.

19. The chip assembly according to claim 1, wherein at least one contact portion is formed as a clamping terminal for clamping the stylus, and the clamping terminal is a part of the conductor.

20. An imaging material box, comprising a housing and an imaging material discharge portion arranged on the housing, the housing being configured to contain an imaging material, wherein the imaging material box further comprises the chip assembly according to claim 1, and the chip assembly is arranged on the housing.
